(19) United States
(12) Patent Application Publication
(10) Pub. No.: US 2025/0280544 A1
(43) Pub. Date: Sep. 4, 2025

(54) SEMICONDUCTOR DEVICES AND DATA STORAGE SYSTEMS INCLUDING THE SAME

(71) Applicant: Samsung Electronics Co., Ltd., Suwon-si (KR)

(72) Inventors: Suhwan Lim, Suwon-si (KR); Kwangsoo Kim, Suwon-si (KR); Taeyoung Kim, Suwon-si (KR); Suseong Noh, Suwon-si (KR); Ilho Myeong, Suwon-si (KR); Sanghyun Park, Suwon-si (KR)

(21) Appl. No.: 18/888,940

(22) Filed: Sep. 18, 2024

(30) Foreign Application Priority Data
Feb. 29, 2024 (KR) 10-2024-0029858

(51) Int. Cl. H10B 51/20; G11C 5/06; H01L 25/065; H10B 51/10; H10B 80/00

(52) U.S. Cl. CPC H10B 51/20; G11C 5/063; H01L 25/0652; H10B 51/10; H10B 80/00; H01L 2225/06506

(57) ABSTRACT

A semiconductor device includes a source structure, a stack structure including interlayer insulating layers and gate electrodes stacked in a first direction perpendicular to an upper surface of the source structure, channel structures disposed in channel holes, penetrating the stack structure in the first direction, the channel structures including a gate dielectric structure and a channel layer, a back gate structure dividing each of the channel structures into a first channel portion and a second channel portion and extending in a second direction perpendicular to the first direction. The back gate structure includes back gate electrode regions disposed between the first channel portion and the second channel portion in each of the channel structures of each of the channel structures, and filling the channel hole, and back gate line regions penetrating the stack structure and connecting the back gate electrode regions to each other in the second direction.

### CROSS-REFERENCE TO RELATED APPLICATION(S)

This application claims benefit of priority under 35 U.S.C. § 119 to Korean Patent Application No. 10-2024-0029858 filed on Feb. 29, 2024 in the Korean Intellectual Property Office, the disclosure of which is incorporated herein by reference in its entirety.

### BACKGROUND

Example embodiments of the present disclosure relate to a semiconductor device and a data storage system including the same.

A semiconductor device able to store high-capacity data in a data storage system requiring data storage has been necessary. Accordingly, a method for increasing data storage capacity of a semiconductor device has been researched. For example, as a method for increasing data storage capacity of a semiconductor device, a semiconductor device including memory cells disposed three-dimensionally, instead of memory cells disposed two-dimensionally, has been suggested.

### SUMMARY

An example embodiment of the present disclosure is to provide a semiconductor device to which a back gate structure dividing a channel structure into a plurality of portions is applied.

An example embodiment of the present disclosure is to provide a data storage system including the semiconductor device.

An example embodiment of the present disclosure is to provide a method of manufacturing the semiconductor device.

According to an example embodiment of the present disclosure, a semiconductor device includes a source structure; a stack structure including interlayer insulating layers and gate electrodes stacked in a first direction perpendicular to an upper surface of the source structure; channel structures disposed in channel holes penetrating the stack structure in the first direction, the channel structures including a gate dielectric structure and a channel layer; a back gate structure dividing each of the channel structures into a first channel portion and a second channel portion and extending in a second direction perpendicular to the first direction, wherein the back gate structure includes back gate electrode regions disposed between the first channel portion and the second channel portion of each of the channel structures, and filling the channel hole; and back gate line regions penetrating the stack structure and connecting the back gate electrode regions to each other in the second direction.

According to an example embodiment of the present disclosure, a semiconductor device includes a plate layer; a stack structure including interlayer insulating layers and gate electrodes stacked on the plate layer in a first direction perpendicular to the plate layer, a vertical direction, and including a channel hole extending in the first direction; a common back gate electrode filling a central region of the channel hole, extending in a second direction perpendicular to the first direction, dividing the channel hole into a first space and a second space, and having a first side surface exposed to the first space and a second side surface exposed to the second space; a first channel portion disposed in the first space of the channel hole and including a first gate dielectric structure, a first channel layer, and a first pad pattern connected to the first channel layer; a second channel portion disposed in the second space of the channel hole and including a second gate dielectric structure, a second channel layer isolated from the first channel layer, and a second pad pattern connected to the first channel layer and isolated from the first pad pattern; and bitlines extending in a third direction perpendicular to the first and second directions and electrically connected to the first and second pad patterns, respectively, wherein the first side surface of the common back gate electrode includes a curved surface protruding toward the first channel layer, and the second side surface includes a curved surface protruding toward the second channel layer.

According to an example embodiment of the present disclosure, a data storage system includes a semiconductor device including an input/output pad; and a controller electrically connected to the semiconductor device through the input/output pad and controlling the semiconductor device, wherein the semiconductor device includes a source structure; a stack structure including interlayer insulating layers and gate electrodes stacked in a first direction perpendicular to an upper surface of the source structure; channel structures disposed in channel holes extending by penetrating the stack structure in the first direction, and including a gate dielectric structure and a channel layer; and a back gate structure dividing each of the channel structures into a first channel portion and a second channel portion and extending in a second direction perpendicular to the first direction, wherein the back gate structure includes back gate electrode regions disposed between the first channel portion and the second channel portion of each of the channel structures, and filling the channel hole; and back gate line regions penetrating the stack structure and connecting the back gate electrode regions to each other in the second direction.

### BRIEF DESCRIPTION OF DRAWINGS

The above and other aspects, features, and advantages of the present disclosure will be more clearly understood from the following detailed description, taken in combination with the accompanying drawings, in which:

FIGS. 1A and 1B are a plan diagram and an enlarged portion of the plan diagram illustrating a semiconductor device according to an example embodiment of the present disclosure;

FIGS. 2A and 2B are cross-sectional diagrams illustrating a cell array of a semiconductor device according to an example embodiment of the present disclosure;

FIGS. 3A and 3B are enlarged cross-sectional diagrams illustrating a portion of a semiconductor device according to an example embodiment of the present disclosure;

FIG. 4A is a circuit diagram illustrating a unit memory cell of a semiconductor device according to an example embodiment of the present disclosure;

FIGS. 4B and 4C are diagrams illustrating a program operation and an erase operation of a semiconductor device according to an example embodiment of the present disclosure;

FIGS. 5A to 5C are enlarged cross-sectional diagrams illustrating a modified example of a semiconductor device according to an example embodiment of the present disclosure;

FIGS. 6 to 12 are an enlarged cross-sectional diagram, a diagram viewed from above, and a cross-sectional diagram illustrating various modified examples of a semiconductor device according to an example embodiment of the present disclosure;

FIGS. 13A to 13K are diagrams illustrating a method of manufacturing a semiconductor device according to an example embodiment of the present disclosure;

FIG. 14 is a diagram illustrating a data storage system including a semiconductor device according to an example embodiment of the present disclosure;

FIG. 15 is a perspective diagram illustrating a data storage system including a semiconductor device according to an example embodiment of the present disclosure; and

FIG. 16 is a cross-sectional diagram illustrating a semiconductor package according to an example embodiment of the present disclosure.

### DETAILED DESCRIPTION

Hereinafter, embodiments of the present disclosure will be described as follows with reference to the accompanying drawings.

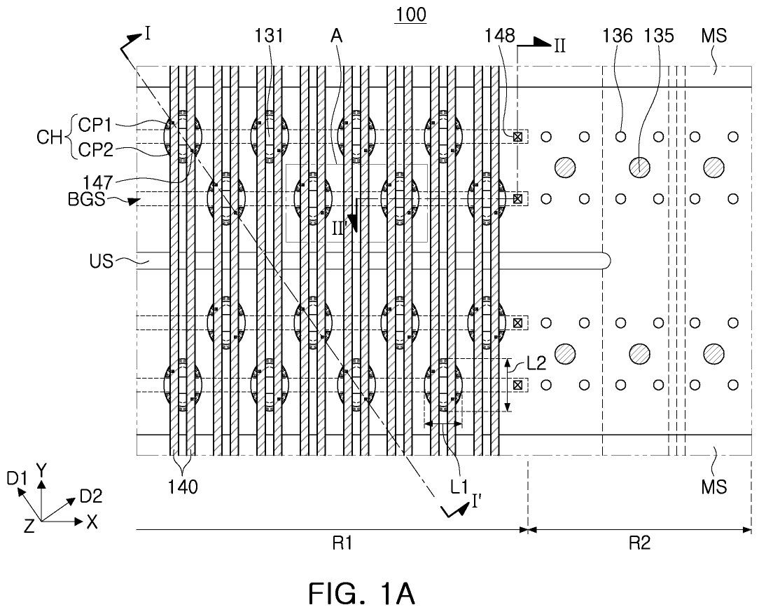

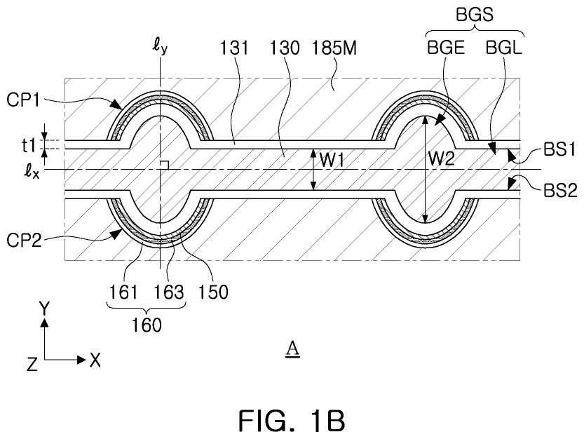

With reference to FIGS. 1A to 4C, a semiconductor device according to an example embodiment will be described.

FIG. 1A is a plan diagram illustrating a semiconductor device according to an example embodiment. FIG. 1B is an enlarged diagram illustrating region “A” in FIG. 1A on a level of an upper surface of the back gate structure.

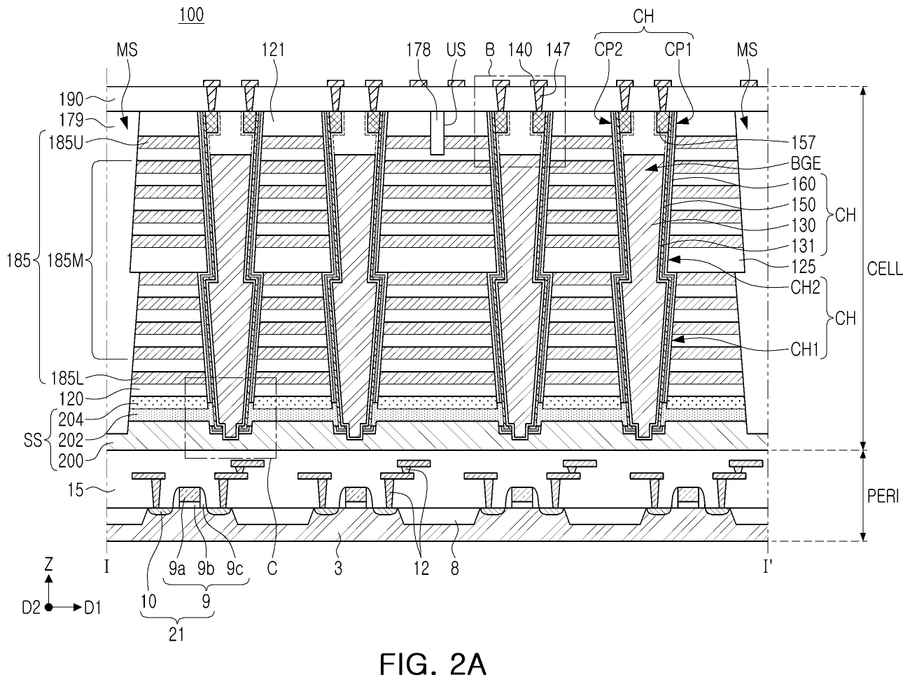

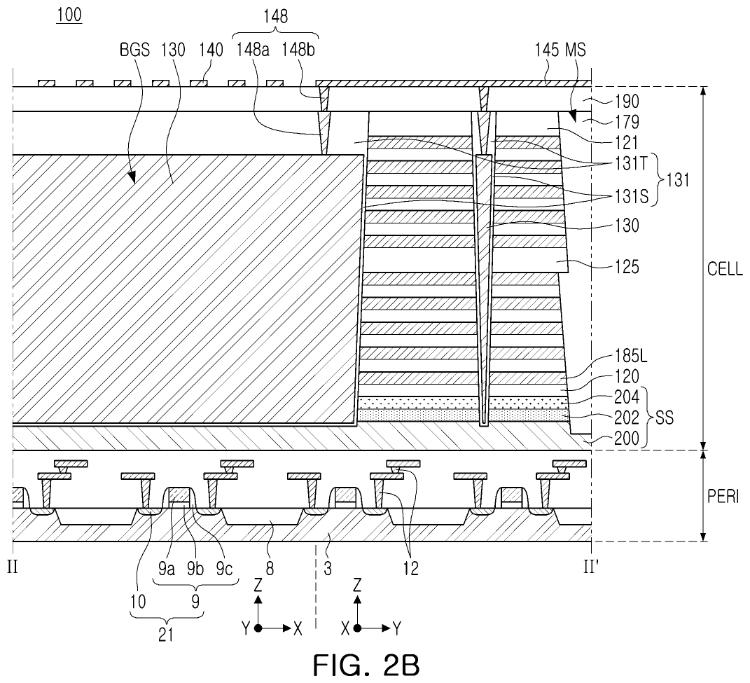

FIGS. 2A and 2B are cross-sectional diagrams illustrating a cell array of a semiconductor device according to an example embodiment. FIG. 2A is a cross-sectional diagram taken along I-I′ in FIG. 1A, and FIG. 2B is a cross-sectional diagram taken along II-II′ in FIG. 1A.

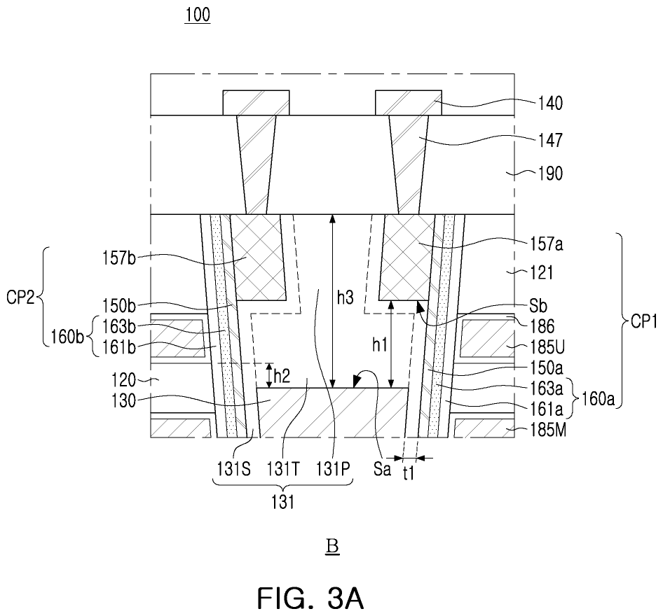

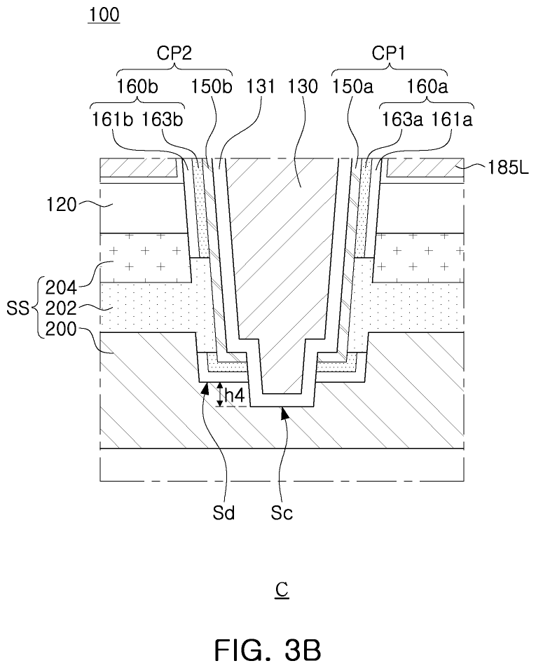

FIGS. 3A and 3B are enlarged cross-sectional diagrams illustrating a portion of a semiconductor device according to an example embodiment. FIG. 3A illustrates region “B” in FIG. 2A in an enlarged manner, and FIG. 3A illustrates region “C” in FIG. 2A in an enlarged manner.

Referring to FIGS. 1A to 3B, the semiconductor device 100 according to an example embodiment may include a first region CELL and a second region PERI. The first region CELL may vertically overlap the second region PERI.

In an example embodiment, the first region CELL may be configured as a memory region in which three-dimensionally arranged memory cells are disposed, and the second region PERI may be configured as a peripheral circuit region.

In an example embodiment, the first region CELL may be referred to as a memory chip structure or a first chip structure, and the second region PERI may be referred to as a peripheral circuit structure or a second chip structure.

The second region PERI may include a first substrate 3, circuit devices 21 on the first substrate 3, a lower interconnection structure 12 and a lower capping layer 15.

The first substrate 3 may include a semiconductor material, such as a group IV semiconductor, a group III-V compound semiconductor, or a group II-VI compound semiconductor. The first substrate 3 may be provided as a bulk wafer or an epitaxial layer. In the first substrate 3, the active region may be defined by device isolation layers. The source/drain regions 10 including impurities may be disposed in a portion of the active region.

The circuit devices 21 may include a transistor. Each of the circuit devices 21 may include a gate structure 9 and a source/drain region 10. The source/drain regions 10 including impurities may be disposed in the first substrate 3 on both sides of the gate structure 9. The gate structure 9 may include circuit gate dielectric layer 9b, a circuit gate electrode 9a, and spacer layers 9c. The spacer layers 9c may be disposed on both sides of the gate structure 9. The circuit gate dielectric layer 9b may include silicon oxide, silicon nitride, or a high-κ material. The circuit gate electrode 9a may include titanium nitride (TiN), tantalum nitride (TaN), tungsten nitride (WN), titanium silicon nitride (TiSiN), tantalum silicon nitride (TaSiN), tungsten silicon nitride (WSiN), tungsten (W), copper (Cu), aluminum (Al), molybdenum (Mo), and ruthenium (Ru). The circuit gate electrode 9a may include a semiconductor layer, for example, a doped polycrystalline silicon layer. According to an example embodiment, the circuit gate electrode 9a may include two or more multiple layers.

The lower interconnection structure 12 may be electrically connected to the gate structure 9 and the source/drain regions 10 of the circuit devices 21. The lower interconnection structure 12 may include lower contact plugs having a cylindrical shape or a truncated cone shape and lower interconnection lines having at least one region having a line shape. A portion of the lower contact plugs may be connected to the source/drain regions 10, and, although not illustrated, the other portion of the lower contact plugs may be connected to the gate structure 9. The lower contact plugs may electrically connect the lower interconnection lines 12 disposed on different levels from an upper surface of the first substrate 3. The lower interconnection structure 12 may include a conductive material, for example, tungsten (W), copper (Cu), or aluminum (Al), and each component may include a diffusion barrier including at least one of titanium (Ti), titanium nitride (TiN), tantalum (Ta), tantalum nitride (TaN), and tungsten nitride (WN). According to example embodiments, the number of the lower contact plugs and the lower interconnection lines included in the lower interconnection structure 12 and the arrangement form thereof may be varied.

The lower capping layer 15 may be disposed on the first substrate 3 and may cover the circuit devices 21 and the lower interconnection structure 12. The lower capping layer 15 may include a plurality of insulating layers. The lower capping layer 15 may include an insulating material, such as silicon oxide, silicon nitride, silicon oxynitride, or silicon oxycarbide.

The first region CELL may include a cell region R1 and an extension region R2 in the X-direction, and may include a source structure SS, gate electrodes 185 stacked on the source structure SS, interlayer insulating layers 120 alternately stacked with the gate electrodes 185, separation region MS penetrating a stack structure ST of the gate electrodes 185 and the interlayer insulating layers 120 and extending in one direction, a channel structure CH penetrating the stack structure ST and the source structure SS, an upper separation region US penetrating a portion of the stack structure ST between the channel structures CH, a back gate structure BGS penetrating the channel structures CH and extending in one direction, contact plugs 147 on the channel structures CH, and an upper interconnection structure on the stack structure ST. The stack structure ST may include interlayer insulating layers 120 and gate electrodes 185 alternately and repeatedly stacked in the vertical direction Z. The stack structure ST may vertically overlap the second region PERI, which may be configured as a peripheral circuit structure.

The cell region R1 may be configured as a memory cell region in which memory cells are disposed, and the channel structures CH may be disposed in the cell region R1, and in the extension region R2, contact plugs 135 and support structures 136 for electrically connecting the memory cells to the peripheral circuit structures PERI may be disposed, and to this end, the gate electrode layers 185 may extend to different lengths in the region, but an example embodiment thereof is not limited thereto.

The source structure SS may include a second substrate 200 and first and second horizontal conductive layers 202 and 204. The second substrate 200 may be configured as a conductive plate layer and may have an upper surface extending in the X-direction and Y-direction. The second substrate 200 may include a semiconductor material, such as a group IV semiconductor, a group III-V compound semiconductor, or a group II-VI compound semiconductor. For example, a group IV semiconductor may include silicon (Si), germanium (Ge), or silicon-germanium (SiGe). The second substrate 200 may be provided as a bulk wafer, an epitaxial layer, an epitaxial layer, a silicon on insulator (SOI) layer, or a semiconductor on insulator (SeOI) layer.

The first and second horizontal conductive layers 202 and 204 may be stacked in order on an upper surface of the second substrate 200. The first and second horizontal conductive layers 202 and 204 may be configured as source layers, and may form a source structure SS together with the second substrate 200. The source structure SS may function as a source line of the semiconductor device 100. As illustrated in FIG. 2A, the first horizontal conductive layer 202 may be directly connected to the channel layer 150 around the channel layer 150.

The first and second horizontal conductive layers 202 and 204 may include a semiconductor material, for example, polycrystalline silicon. For example, the first horizontal conductive layer 202 may be configured as a layer doped with N-type impurities. The second horizontal conductive layer 204 may be configured as a doped layer, or may be an intrinsic semiconductor layer and a layer including impurities diffused from the first horizontal conductive layer 202. However, the material of the second horizontal conductive layer 204 is not limited to a semiconductor material, and may be replaced with an insulating layer in example embodiments.

The gate electrodes 185 may be vertically stacked and spaced apart from each other on the second substrate 200 and may form the stack structure ST. The gate electrodes 185 may be disposed between the second substrate 200 and the upper interconnection structure. The gate electrodes 185 may form an upper gate stack group and a lower gate stack group. The upper gate stack group may be disposed on the lower gate stack group. An intermediate interlayer insulating layer 125 disposed between the lower gate stack group and the upper gate stack group may have a relatively great thickness (e.g., a thickness greater than a gate electrode 185 and an interlayer insulating layer 120), but an example embodiment thereof is not limited thereto.

The gate electrodes 185 may include electrodes forming a ground select transistor, memory cells, and string select transistor in order from the second substrate 200. Depending on storage capacity of the semiconductor device 100, the number of the gate electrodes 185 forming memory cells may be determined. In example embodiments, the number of the gate electrodes 185 forming a string select transistor and a ground select transistor may be one or two or more, respectively, and may have the same structure or different structures as that of the gate electrodes 185 of the memory cells.

The gate electrodes 185 may include lower gate electrodes 185L, intermediate gate electrodes 185M, and upper gate electrodes 185U.

The intermediate gate electrodes 185M may form wordlines of the memory cells, and the intermediate gate electrodes 185M may also be referred to as wordlines.

In an example, at least one of the lower gate electrodes 185L may be configured as a lower select gate electrode, and at least one of the upper gate electrodes 185U may be configured as an upper select gate electrode. For example, at least one of the lower gate electrodes 185L may be configured as a gate electrode of a ground select transistor, and at least one of the upper gate electrodes 185U may be configured as a gate electrode of a string select transistor. In an example, at least one of the lower gate electrodes 185L and the upper gate electrodes 185U may be configured as an erase control gate electrode generating a GIDL current due to a gate induced drain leakage (GIDL) phenomenon in a NAND flash memory device and used for an erase operation.

The gate electrodes 185 may include a conductive material. For example, each of the gate electrodes 185 may be formed of polysilicon, W, Ru, Mo, Nb, Ni, Co, Ti, Ta, TiN, TaN, WN, NbN, TiAl, TiAlN, TiSi, TiSiN, TaSi, TaSiN, RuTiN, NiSi, CoSi, or a combination thereof, but an example embodiment thereof is not limited thereto. For example, each of the gate electrodes 185 may include a single layer or multiple layers of the materials described above. A diffusion barrier 186 may be further disposed on a surface of the gate electrodes 185. For example, the diffusion barrier 186 may include tungsten nitride (WN), tantalum nitride (TaN), titanium nitride (TiN), or a combination thereof. The diffusion barrier 186 may not extend along side surfaces of the separation regions MS, side surfaces of the back gate structures BGS, and side surfaces of the upper separation region US.

The interlayer insulating layers 120 may be disposed alternately with the gate electrodes 185. Similarly to the gate electrodes 185, the interlayer insulating layers 120 may be spaced apart from each other in the vertical direction (Z-direction) on an upper surface of the source structure SS. The interlayer insulating layers 120 may include an insulating material such as silicon oxide. Among the interlayer insulating layers 120, the uppermost interlayer insulating layer 121 may have a thickness greater than that of the other interlayer insulating layers 120, similarly to the intermediate interlayer insulating layer 125.

The separation regions MS may be disposed to extend by penetrating the gate electrodes 185 in the Z-direction. The separation regions MS may be connected to the second substrate 200 by penetrating the entirety of the gate electrodes 185 stacked on the second substrate 200. The separation insulating layer 179 may be disposed in the separation regions MS. The separation region MS may have a shape of which a width may decrease toward the second substrate 200 due to a high aspect ratio. The separation region MS may extend in the X-direction and may isolate the gate electrodes 185 from each other in the Y-direction.

According to example embodiments, a conductive layer may be further disposed in the separation insulating layer 179 in the separation regions MS. The separation insulating layer 179 may include an insulating material such as silicon oxide or silicon nitride, for example, silicon oxide, silicon nitride, or silicon oxynitride.

The upper separation region US may extend in the X-direction between the gate separation regions MS adjacent to the Y-direction. The upper separation region US may be disposed to penetrate a portion of the gate electrodes 185, including the upper gate electrodes 185U. The upper separation region US may, for example, isolate the gate electrodes 185U from each other in the Y-direction, as illustrated in FIG. 2A. However, the number of the gate electrodes 185 isolated by the upper separation region US may be varied in example embodiments. The upper separation region US may include an insulating material 178, for example, silicon oxide, silicon nitride, or silicon oxynitride.

The channel structures CH may be disposed to continuously penetrate the stack structure ST and the source structure SS. The channel structures CH may form a memory cell string, and may be spaced apart from each other while forming rows and columns in the cell region R1 of the first region CELL. The channel structures CH may be disposed to form a grid pattern on an X-Y plane or a zigzag pattern in one direction. The channel structures CH may penetrate the gate electrodes 185, may extend in a vertical direction perpendicular to an upper surface of the second substrate 200, for example, in the Z-direction, and may have a pillar shape, and may have an inclined side surface having a width decreasing toward the second substrate 200 depending on an aspect ratio. As illustrated in FIG. 1B, the channel structures CH may have an oval shape, an elongated shape, a quadrangular shape, or a rounded quadrangular shape having a long-direction length in the X-direction or the Y-direction.

In the channel structures CH, as an example, the long-direction length L2 in the Y-direction may be greater than a short-direction length L1 in the X-direction perpendicular to the Y-direction. The long-direction length L2 may range, for example, from about 80 nm to about 200 nm, but an example embodiment thereof is not limited thereto, and may be determined depending on a pitch of the bitlines 140 of the upper interconnection structure. The “pitch” may refer to a distance between centers of components, or a sum of a width and a spacing distance between components. The pitch of the bitlines 140 may range from about 20 nm to about 70 nm, for example. For example, the channel structures CH may be arranged at a pitch greater than the pitch of the bitlines 140 in the X-direction. The long-direction length L2 and the pitch of the channel structures CH may be determined in a range in which first and second channel portions CP1 and CP2 of the channel structures CH may be connected to the different bitlines 140, respectively.

Each of the channel structures CH may be divided into the first and second channel portions CP1 and CP2 by the back gate structure BGS penetrating a center and extending in the X-direction. Each of the first and second channel portions CP1 and CP2 may form a memory cell string. Each of the first and second channel portions CP1 and CP2 may have, for example, a hemi-cylinder or semi-pillar shape corresponding to a half of an elliptical pillar. The first channel portion CP1 may have a shape in which the second channel portion CP2 rotates by 180 degrees.

Each of the channel structures CH may have a form in which lower and upper vertical structures CH1 and CH2 penetrating the lower gate stack group and the upper gate stack group of the gate electrodes 185 in the Z-direction are connected to each other, and may have a bent portion due to a difference or a change in width of a lower surface of the upper vertical structure CH2 and a width of an upper surface of the lower vertical structure CH1 in the connection region.

Each of the channel structures CH may include a common back gate electrode region BGE, a first insulating layer 131, a channel layer 150, and a gate dielectric structure 160.

The common back gate electrode region BGE may have a pillar disposed in the central region of a channel hole filled by channel structure CH and extending in the Z-direction. The common back gate electrode region BGE may partially penetrate the second substrate 200, and may be electrically and physically spaced apart from the second substrate 200.

The common back gate electrode region BGE in the channel hole may be connected to a common back gate electrode region BGE in an adjacent channel hole through a back gate line region BGL in the X-direction. A plurality of the common back gate electrode regions BGE in a row in the X-direction and the back gate line regions BGL connecting them may form the back gate structure BGS.

Each of the back gate structures BGS may be disposed parallel to the separation region MS and the upper separation region US on an X-Y plane, and may be disposed in the cell region R1. Each of the back gate structures BGS may penetrate the channel structures CH in a row between the separation region MS and the upper separation region US, may penetrate the stack structure ST between neighboring channel structures CH and may extend in the X-direction. The back gate structure BGS may cross the channel structures CH in the X-direction, and may divide the channel structures CH into first and second channel portions CP1 and CP2.

A region of the back gate structure BGS penetrating the channel structure CH and facing the channel layer 150 may be defined as the common back gate electrode region BGE, and the line region connecting neighboring common back gate electrode regions BGE to each other may be defined as back gate line region BGL. The back gate structure BGS across a row of the channel structures CH may have a form in which the common back gate electrode regions BGE and the back gate line regions BGL may be alternately connected to each other. The back gate structure BSG may include two side surfaces BS1 and BS2 parallel to each other in the X-direction.

In the back gate line region BGL, two parallel side surfaces BS1 and BS2 may extend in the X-direction, a distance between two side surfaces BS1, BS2 may be a maximum first width W1 in the Y-direction, and as the second substrate 200 approaches, a distance between the two side surfaces BS1 and BS2 may decrease. A length of the back gate line region BGL in the X-direction may be equal to or smaller than a length of the cell region R1 and may be smaller than a length of the upper separation region US. The first width W1 may be smaller than the short-direction length L1 of the channel structure CH.

The common back gate electrode region BGE may be disposed in a center of the channel hole and filling a central region of the channel hole, and may be an extension region extending outwardly in a curved manner along a shape of the channel hole in the two parallel side surfaces BS1 and BS2 of the back gate line region BGL on the X-Y plane. Accordingly, the two side surfaces BS1 and BS2 may have curved surfaces protruding toward each channel layer 150. The common back gate electrode region BGE may be a distance between the two side surfaces BS1 and BS2, and may have a maximum second width W2 in the Y-direction. The second width W2 may be greater than the first width W1, and may be disposed on the Y-direction axis 1_{y} intersecting the center of the channel structure CH. The common back gate electrode region BGE may be disposed to penetrate the center of the channel structures CH. A length of the curved extension region of the common back gate electrode region BGE in the X-direction may be smaller than the short-direction length L1 of the channel structure CH, and the back gate line region BGL for connecting neighboring common back gate electrode regions BGE to each other may extend into the channel structure CH.

An internal space of a channel hole may be divided into two first spaces and second spaces by the back gate structure BGS, and the first channel portion CP1 and the second channel portion CP2 may be disposed in the first space and the second space, respectively. In the first channel portion CP1 and the second channel portion CP2, the channel layer 150 forming the channel structure CH may be divided into two a hemi-cylinder or semi-pillar shape corresponding to a half of an elliptical pillar regions and may be disposed to form the first channel layer and second channel layer 150a and 150b, and the gate dielectric structure 160 gate dielectric structure 160 may be divided into two a hemi-cylinder or semi-pillar shape corresponding to a half of an elliptical pillar regions and may form the first gate dielectric structure and the second gate dielectric structure 160a and 160b. The first channel portion CP1 and second channel portion CP2 may be disposed symmetrically with respect to the X-direction axis lx of the back gate structure BSG in a channel hole, may share the back gate structure BSG and may receive a back gate voltage in common.

The back gate structure BGS may penetrate the entire channel structures CH in the Z-direction. A lower end of the back gate structure BGS may be disposed on a level the same as or lower than a level of a lower end of the channel structures CH. Specifically, a lower end of the back gate structure BGS may be disposed on a level lower than a level of a lower surface of channel layer 150 on a lower end of the channel structures CH.

The upper surface Sa of the back gate structure BGS may be disposed on a level lower than a level of a lower surface of the upper gate electrodes 185U and may have a second spacing distance h2. The second spacing distance h2 may be greater than 0 and may be less than a thickness of the interlayer insulating layer 120. Accordingly, the back gate structure BGS may be disposed on a level corresponding to the intermediate gate electrodes 185M. When the upper gate electrodes 185U function as the gate electrodes of the string select transistor, the string select transistor may have fast on-off operation properties without the back gate electrode region BGE.

Due to a high aspect ratio, the back gate structure BGS may have a shape of which an overall width may be reduced toward the second substrate 200, and a width of the common back gate electrode region BGE may change rapidly or discontinuously along a bent portion of the channel structure CH in the channel structure CH. The back gate line region BGL may not have a bent portion and simply a width continuously may decrease from the first width W1, which is a maximum width on an upper surface Sa, toward the second substrate 200.

The back gate structure BGS may be connected to the back gate interconnection 145 of the upper interconnection structure by the back gate contact 148 in the boundary region between the cell region R1 and the extension region R2. As described above, the common back gate electrode regions BGE for the plurality of channel structures CH forming a row may not be in contact with each of the channel structures CH, and the back gate voltage may be applied simultaneously by a back gate contact 148 in the boundary region.

Also, as illustrated in FIG. 2B, a block, that is, the back gate contacts 148 of the back gate structures BGS of in a plurality of rows between the separation regions MS may be simultaneously connected by the back gate interconnection 145 of the upper interconnection structure. Accordingly, the back gate electrode regions BGE of a block may be driven by receiving the same back gate voltage, but an example embodiment thereof is not limited thereto, and each of the back gate structure BGS may be driven in various manners by receiving an individual back gate voltage.

The back gate structure BGS may include a conductive material layer 130. The conductive material layer 130 may include a barrier layer (not illustrated) on a side surface and a lower surface, and the barrier layer may be configured as a diffusion barrier. As a conductive material layer 130, at least one of doped semiconductor (e.g., doped silicon, or the like), metal (e.g., tungsten, copper, aluminum, or the like), conductive metal nitride (e.g., titanium nitride, tantalum nitride, or the like) or transition metal (e.g., titanium, tantalum, or the like) may be included, and the barrier layer may include at least one selected from titanium (Ti), titanium nitride (TiN), tantalum (Ta), tantalum nitride (TaN), and tungsten nitride (WN).

The first insulating layer 131 covering the conductive material layer 130 of the back gate structure BGS may be disposed.

The first insulating layer 131 may include a first portion 131S conformally covering a side surface and a bottom surface of the conductive material layer 130, and a second portion 131T disposed on an upper surface Sa of the back gate electrode region BGE and the back gate line region BGL.

The first portion 131S may be conformally disposed to have the same thickness t1 along a side surface and a bottom surface of the back gate electrode region BGE and the back gate line region BGL and an external surface of the back gate structure BGS. The first insulating layer 131 may function as a back gate dielectric layer between the channel layer 150 and the common back gate electrode region BGE in the channel structure CH by the first portion 131S, and may function as an insulating layer blocking conduction of the gate electrodes 185 and the back gate structure BGS on an interfacial surface between the stack structure ST and the back gate structure BGS. The first portion 131S may be disposed between the second substrate 200 and a bottom surface of the back gate structure BGS and may block conduction of the second substrate 200 and the back gate structure BGS.

The second portion 131T may be disposed to fill a space between the upper surface Sa of the back gate electrode region BGE and the back gate line region BGL and the lower surface of the upper insulating layer 190. The second portion 131T may fill a space between the upper surface Sa and a lower surface of the upper insulating layer 190. The second portion 131T may fill an opening region formed by etching such that an upper surface of the common back gate electrode region BGE may be disposed on a level lower than a level of the lower surface of the upper gate electrode 185U in the channel structure CH, and may insulate between the pad pattern 157 and the back gate electrode region BGE.

The second portion 131T may fill a first distance h1, which is a distance between the lower surface Sb of the pad pattern 157 and the upper surface Sa of the back gate electrode region BGE. Also, a protrusion 131P filling the spacing between the pad patterns 157 may be further included. Accordingly, a thickness of the second portion 131T may be equal to a third distance h3, which is a sum of the thickness of the protrusion 131P and the first distance h1 in a channel hole, and may be formed by completely filling the channel hole. Accordingly, the second portion 131T of the first insulating layer 131 in the channel structure CH may have a bent shape to have different widths in the Z-direction. The second portion 131T may extend to the same width as that of the protrusion 131P, may be formed without a bent portion on the upper surface Sa of the back gate line region BGL, and may have a thickness of the third distance h3. According to an example embodiment, the first portion 131S and the second portion 131T of the first insulating layer 131 may include different materials. As an example, the first portion 131S of the first insulating layer 131 may include a silicon oxide layer, and the second portion 131T may include a high-κ material different from the silicon oxide layer, but an example embodiment thereof is not limited thereto, and the same silicon oxide film may be included.

An upper surface of the first insulating layer 131 may be disposed to be in contact with a lower surface of the upper insulating layer 190, and may be coplanar with the pad pattern 157.

The lower surface Sc of the first insulating layer 131 may be disposed on a level the same as or lower than a level of the lower surface Sd of the channel structure CH. The lower surface Sc of the first insulating layer 131 may be disposed on a level lower than a level of the lower surface of the channel layer 150 to completely cut the channel layer 150 from the lower surface Sd of the channel structure, and at least an upper surface of the first insulating layer 131 (a lower surface of the back gate structure) on a lower end of the back gate structure BGS may be disposed on a level lower than a level of a lower surface of the channel layer 150 on a lower end of the channel structure CH. Accordingly, as illustrated in FIG. 3B, in the lower surface Sd of the channel structure CH, the internal side surface of the first channel layer 150a of the first channel portion CP1 and the internal side surface of the second channel layer 150b of the second channel portion CP2 may be completely physically and electrically isolated from each other with the first insulating layer 131 therebetween.

Each of the channel structures CH may include a channel layer 150 disposed in a center and a gate dielectric structure 160 surrounding the channel layer 150. The channel layer 150 may include a first channel layer 150a and a second channel layer 150b of the first channel portion CP1 and the second channel portion CP2, and may be disposed by surrounding the first insulating layer 131 between an internal side surface of the gate dielectric structure 160 and an external side surface of the first insulating layer 131. Accordingly, each of the first channel layer 150a and the second channel layer 150b of the first channel portion CP1 and the second channel portion CP2 may have a hemi-cylinder or semi-pillar shape corresponding to a half of an elliptical pillar. In each of channel layers 150a and 150b, the lower channel structure CH1 and the upper channel structure CH2 may be disposed consecutively to extend from an upper end of the channel structure CH to a lower end along the channel hole. Accordingly, an upper end of each of the channel layers 150a and 150b may be disposed on a level higher than the upper surface Sa of the common back gate electrode region BGE. The channel layers 150a and 150b may not include a region extending horizontally from a lower end of the channel structure CH to an upper surface of the gate dielectric structure 160, but an example embodiment thereof is not limited thereto. The channel layers 150a and 150b may be in contact with the first horizontal conductive layer 202 through an external side surface in a contact region including a region on a level corresponding to the first horizontal conductive layer 202. Accordingly, the channel layers 150a and 150b may be electrically connected to the source structure SS.

The channel layers 150a and 150b may include a semiconductor material such as polycrystalline silicon or single crystal silicon, and the semiconductor material may be an undoped material or a material including P-type or N-type impurities. The channel layers 150a and 150b may include a semiconductor material. For example, the channel layers 150a and 150b may include at least one of doped silicon, undoped silicon, doped polysilicon, undoped polysilicon, or oxide semiconductor. The oxide semiconductor may be indium gallium zinc oxide (IGZO), but an example embodiment is not limited thereto. For example, the oxide semiconductors may include at least one of indium tungsten oxide (ITO), indium tin gallium oxide (ITGO), indium aluminum zinc oxide (IAZO), indium gallium oxide (IGO), indium tin zinc oxide (ITZO), zinc tin oxide (ZTO), indium zinc oxide (IZO), zinc oxide (ZnO), indium gallium silicon oxide (IGSO), indium oxide (InO), tin oxide (SnO), titanium oxide (TiO), zinc oxynitride (ZnON), magnesium zinc oxide (MgZnO), indium zinc oxide (InZnO), indium gallium zinc oxide (InGaZnO), zirconium indium zinc oxide (ZrInZnO), hafnium indium zinc oxide (HfInZnO), tin indium zinc oxide (SnInZnO), aluminum tin indium zinc oxide (AlSnInZnO), silicon indium zinc oxide (SiInZnO), zinc tin oxide (ZnSnO), aluminum zinc tin oxide (AlZnSnO), gallium zinc tin oxide (GaZnSnO), zirconium zinc tin oxide (ZrZnSnO), and indium gallium silicon oxide (InGaSiO).

Each of the first channel portion CP1 and the second channel portion CP2 of the channel structures CH may further include gate dielectric structures 160a and 160b on external side surfaces of the channel layers 150a and 150b, and one layer of the gate dielectric structure 160 may be separated into the gate dielectric structures 160a and 160b of the first channel portion CP1 and the second channel portion CP2 by the back gate structure BGS in a channel hole. Accordingly, each of the gate dielectric structures 160a and 160b may have a hemi-cylinder or semi-pillar shape corresponding to a half of an elliptical pillar similarly to the channel layers 150a and 150b. As illustrated in FIG. 3B, the gate dielectric structures 160a and 160b may be disposed in the channel hole in regions other than the contact region in which the first horizontal conductive layer 102 and the channel layer 150 may be in contact with each other. In the contact region, the gate dielectric structures 160a and 160b may be partially removed to expose the channel layer 150.

The gate dielectric structures 160a and 160b may include a plurality of stack structures.

The gate dielectric structures 160a and 160b may further include data storage layers 163a and 163b on an external side surface of the channel layers 150a and 150b and the second insulating layers 161a and 161b on the data storage layers 163a and 163b.

The data storage layers 163a and 163b may be disposed between the second insulating layers 161a and 161b and the channel layers 150a and 150b. Each of the data storage layers 163a and 163b may have a first side surface 163S1 and a second side surface 163S2 opposing each other. The first side surface 163S1 may face the channel layers 150a and 150b, and the second side surface 163S2 may face the second insulating layers 161a and 161b.

The data storage layers 163a and 163b may be ferroelectric layers. The data storage layers 163a and 163b may have polarization properties depending on an electric field and may have remnant polarization by a dipole even in the absence of an external electric field. The data storage layers 163a and 163b may record data using the polarization state in the ferroelectric layer. The data storage layers 163a and 163b opposing the intermediate gate electrodes 185M, which may be wordlines, may be regions storing data using a polarization state.

The data storage layers 163a and 163b may be configured as a ferroelectric layer including an Hf-based compound, a Zr-based compound, and/or an Hf—Zr-based compound. For example, the Hf-based compound may include a HfO-based ferroelectric material, the Zr-based compound may include a ZrO-based ferroelectric material, and the Hf—Zr-based compound may include a hafnium zirconium oxide (HZO)-based ferroelectric material.

The data storage layers 163a and 163b may include a ferroelectric material doped with at least one of impurities, such as Zr, C, Si, Mg, Al, Y, N, Ge, Sn, Gd, La, Sc, and Sr. For example, the ferroelectric layer of the data storage layers 163a and 163b may be a material doped with impurities in at least one of HfO₂, ZrO₂ and HZO, and at least one of Zr, C, Si, Mg, Al, Y, N, Ge, Sn, Gd, La, Sc and Sr. For example, the ferroelectric layer of the data storage layers 163a and 163b may include Hf₁₋ₓZrₓO₂ (0≤x≤1), (Al, C, N, Gd, Y, Ta, La, Si)-doped HfO₂, or Al₁₋ₓScₓN (0≤x≤1).

The ferroelectric layers of the data storage layers 163a and 163b are not limited to the above-described material and may include a material having ferroelectric properties for storing data. For example, the ferroelectric layer of the data storage layers 163a and 163b may include at least one of BaTiO₃, PbTiO₃, BiFeO₃, SrTiO₃, PbMgNdO₃, PbMgNbTiO₃, PbZrNbTiO₃, PbZrTiO₃, KNbO₃, LiNbO₃, GeTe, LiTaO₃, KNaNbO₃, BaSrTiO₃, HF_{0.5}Zr_{0.5}O₂, PbZrₓTi1-xO3(0<x<1), Ba(Sr, Ti)O₃, Bi₄₋ₓLaₓTi3O12(0<x<1, SrBi₂Ta₂O₉, Pb₅Ge₅O₁₁, SrBi₂Nb₂O₉, and YMnO₃.

The thickness of the data storage layers 163a and 163b may be equal to or greater than about 10 Å, and may be equal to or less than about 130 Å.

The second insulating layers 161a and 161b disposed between the data storage layers 163a and 163b and the gate electrode 185 may be disposed in a hemi-cylinder or semi-pillar shape corresponding to a half of an elliptical pillar covering an external side surface of the data storage layers 163a and 163b. The second insulating layers 161a and 161b may be in contact with the data storage layers 163a and 163b through an internal side surface, and may be in contact with the gate electrodes 185 through the external side surface. The second insulating layers 161a and 161b may prevent carriers from moving to the data storage layers 163a and 163b and/or the gate electrodes 130 or may prevent the material from spreading. Accordingly, the polarization state in the data storage layers 163a and 163b may be maintained stably, and ferroelectric properties of data storage layers 163a and 163b may be maintained stably.

The second insulating layers 161a and 161b may include an insulating material. Similarly to the first insulating layer 131, the second insulating layers 161a and 161b may include an insulating material such as silicon oxide, but an example embodiment thereof is not limited thereto. In the channel structures CH, relative thicknesses of the first insulating layer 131, the channel layers 150a and 150b, the data storage layers 163a and 163b and the second insulating layers 161a and 161b may be varied.

The first channel portion CP1 and the second channel portion CP2 in each of the channel structures CH may further include pad patterns 157a and 157b, respectively. The pad patterns 157a and 157b may be disposed on an upper end of the channel structure CH, the lower surface Sb may be spaced apart from the upper surface Sa of the common back gate electrode region BGE by the first distance h1, and an upper surface may form an upper surface of the channel structure CH. Each of the pad patterns 157a and 157b may be disposed in a space between the protrusion 131P of the first insulating layer 131 and the channel layer 150 in an upper portion of the channel structure CH, and may have an upper surface having a shape similarly to a semicircular shape or a semi-elliptic shape. Accordingly, one side of the pad patterns 157a and 157b may be connected to the channel layers 150a and 150b, and the protrusion 131P of the first insulating layer 131 may be exposed to a region between the pad patterns 157a and 157b opposing each other, thereby preventing short circuit with neighboring pad patterns 157a and 157b. The pad patterns 157a and 157b may be disposed on a level higher than a level of the upper gate electrode 185U among the gate electrodes 185. The pad patterns 157a and 157b may include a conductive material, for example, doped polysilicon with N-type conductivity.

When the first pad pattern 157a and the second pad pattern 157b of the channel structure CH are disposed side by side in the Y-direction, and among the plurality of upper interconnection structures extending in the Y-direction, the bitlines 140 may be selectively connected to the pad patterns 157a and 157b, respectively. The connection between the pad patterns 157a and 157b and the bitline may be formed by the contact plugs 147 as illustrated in FIG. 2A, two contact plugs 147 may be disposed on a channel structure CH. The first channel portion CP1 may be physically and electrically connected to a first of the two contact plugs 147. The second channel portion CP2 may be physically and electrically connected to a second of the two contact plugs 147. The contact plugs 147 may have a cylindrical shape, and may have an inclined side surface of which a width may decrease toward the second substrate 200 depending on an aspect ratio. The contact plugs 147 may connect the first and second channel portions CP1 and CP2 to the bitlines 140.

The upper interconnection structure including the bitlines 140 may be connected to the contact plugs 147 and may extend in the Y-direction, and may be electrically connected to the first and second channel portions CP1 and CP2, respectively. The upper interconnection structure may be configured as the bitlines 140 and the back gate interconnections 145 or an interconnection structure electrically connected thereto. Two or more bitlines 140 may be arranged, for example, three bitlines 140, on the channel structure CH, but an example embodiment thereof is not limited thereto.

The upper interconnection structure may include a conductive material, for example, tungsten (W), copper (Cu), aluminum (Al), or the like, and each component may further include a diffusion barrier including at least one of titanium (Ti), titanium nitride (TiN), tantalum (Ta), tantalum nitride (TaN), and tungsten nitride (WN). According to example embodiments, the number of layers included in the upper interconnection structure and the arrangement thereof may be varied.

The back gate contact 148 connecting the back gate structure BGS to the upper interconnection structure may be disposed in a boundary region of the cell region R1 and the extension region R2, and may include a first plug 148a in contact with an upper surface of the back gate structure BGS and penetrating the second portion 131T of the first insulating layer 131, and a second plug 148b connected perpendicularly to the first plug 148a, penetrating the upper insulating layer 190, and connected to the back gate interconnection 145 of the upper interconnection structure.

As illustrated in FIGS. 1A to 3B, the channel structure CH may be divided into two channel portions CP1 and CP2 by the back gate structure BGS extending in the X-direction, and each of the divided channel portions CP1 and CP2 may implement a memory cell array. Also, the two channel portions CP1 and CP2 divided in a channel hole may be disposed symmetrically around the back gate structure BGS, and the back gate structure BGS in the channel hole central region may be a common back gate electrode region BGE, such that the back gate voltage may be applied to both the channel portions CP1 and CP2 simultaneously. Accordingly, since the two channel portions CP1 and CP2 share the back gate electrode region BGE, miniaturization and maximization of memory capacity of the device may be implemented, and overall memory density may be extended. Also, a back gate electrode region BGE may be included, and the pad patterns 157a and 157b spaced apart from the back gate electrode region BGE and in contact with each channel layer 150a and 150b, respectively, may be included, the insulating layer 131 may be disposed between two pad patterns 157a and 157b, such that short circuits in the two channel portions CP1 and CP2 in a channel hole may be prevented. The back gate electrode region BGE may not be exposed to an upper portion of the channel structure CH similarly to the pad patterns 157a and 157b, may be disposed to have an upper surface Sa on a level lower than a level of a lower surface of the upper gate electrode 185U, and the back gate contact 148 may be formed on an edge of the cell region R1 for contact with an external entity, such that, since it may not be necessary to ensure an area in the channel structure CH for the back gate contact 148, such that the area for bitline contact may be sufficiently ensured.

Also, in the semiconductor device 100, since the gate dielectric structure 160 may include the ferroelectric layer 163, an equivalent oxide thickness (EOT) may be reduced as compared to a charge trap type semiconductor device including a charge trap layer, and accordingly, a current may be increased. Accordingly, by dividing the channel structure CH into first and second channel portions CP1 and CP2, even when an area of the channel layer 150 of each memory cell is reduced, worst on cell current properties, an on-current in a state in which the entirety of cells are programmed, may be ensured. Also, by dividing the channel structure CH, capacitance per memory cell may be reduced, thereby reducing delay and improving read operation time.

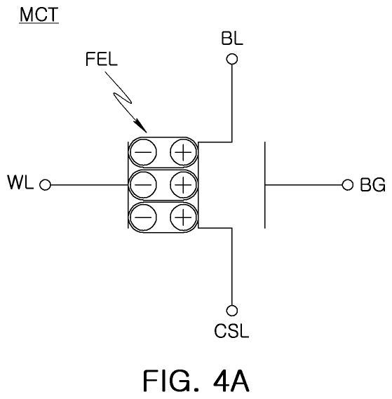

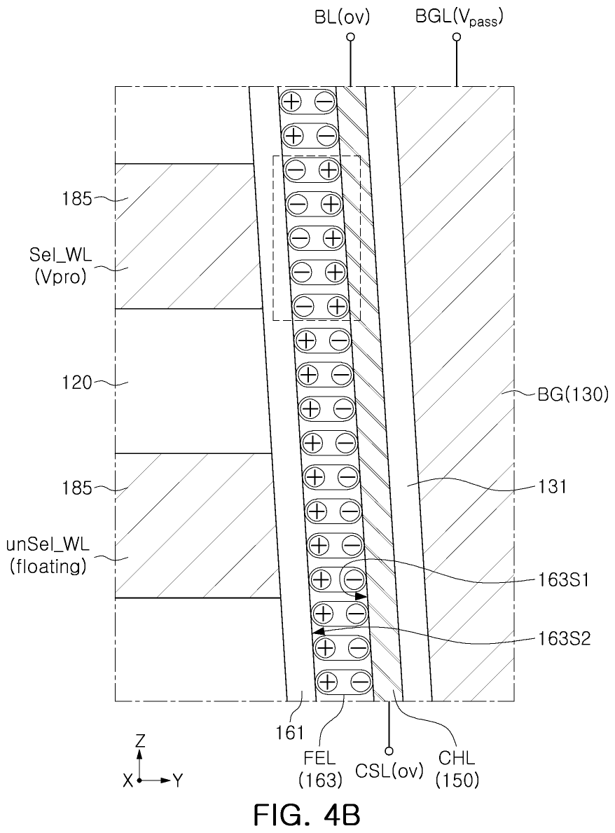

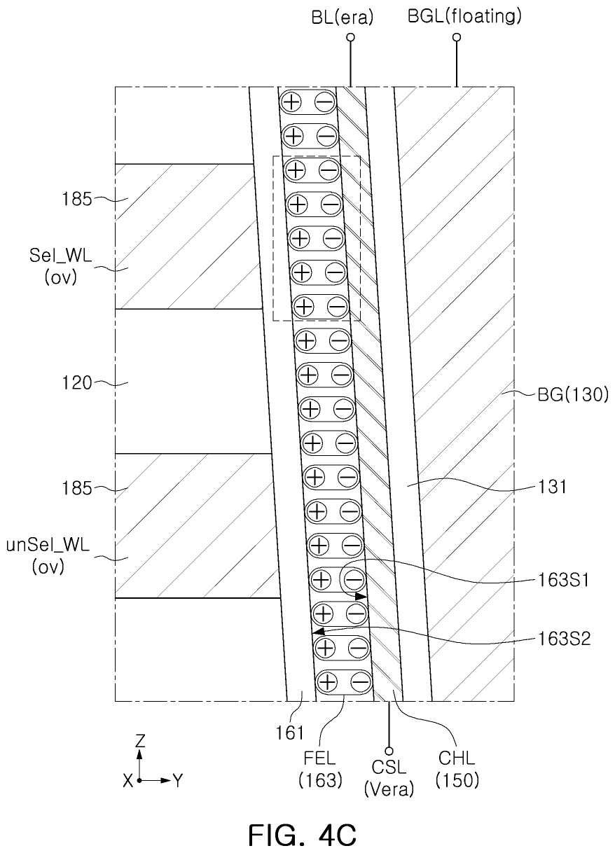

Hereinafter, an operation of the semiconductor device 100 including the memory cell transistor MCT will be described with reference to FIGS. 4A to 4C.

FIG. 4A is a circuit diagram illustrating a unit memory cell of a semiconductor device according to an example embodiment. FIG. 4B is a state diagram during program operation of a semiconductor device according to an example embodiment, and FIG. 4C is a state diagram during an erase operation of a semiconductor device according to an example embodiment.

Referring to FIG. 4A, each of the memory cells MCT may be controlled by a wordline WL and a back gate line BG. Each of the memory cells MCT may include a gate electrode, a source electrode, a drain electrode, a channel between the source electrode and the drain electrode, and a back gate electrode BG. A gate electrode of each of the memory cells MCT may be connected to a wordline WL, and the back gate electrode BG may be connected to the back gate structure BGS. The bitline BL may be connected to a drain electrode, and the common source line CSL may be connected to a source electrode. Each of the memory cells MCT may include a ferroelectric film FEL as a memory film (or data storage film) between the channel region and the back gate electrode BG.

The ferroelectric film FEL may have a spontaneous dipole (electric dipole), that is, spontaneous polarization, as charge distribution in each of the memory cells MCT may be non-centrosymmetric. The ferroelectric film FEL may have remnant polarization by dipole even in the absence of an external electric field. Also, the direction of polarization may be switched by an external electric field.

That is, the ferroelectric film FEL may have a positive or negative polarization state, and the polarization state may vary depending on an electric field applied to the ferroelectric film FEL during a program operation. A polarization state of the ferroelectric film FEL may be maintained even when power is turned off, such that the semiconductor memory device may operate as a nonvolatile memory device. In example embodiments, a polarization state of the ferroelectric film FEL may be determined by a voltage difference between the channel region and the gate electrode.

As an example, during a program operation, the channel region in the memory cell MCT may be depleted by a program voltage applied to the gate electrode, and polarity of the ferroelectric film FEL may be changed by a voltage difference between the program voltage applied to the gate electrode and the channel region. A voltage difference between the program voltage and the channel region may be greater than a minimum voltage required to change polarization of the ferroelectric film FEL.

During an operation to read data from the memory cell MCT, data stored in the memory cell MCT may be read by measuring a current flowing through the channel region of the selected memory cell MCT. Also, during a program operation, no voltage may be applied to the gate electrode of the memory cell MCT not selected in the back gate electrode BG, and a pass voltage may be applied to the back gate electrode BG, such that influence of a polarization state caused by a high program voltage of the neighboring gate electrode may be reduced.

Specifically, as illustrated in FIG. 4B, a program operation may apply a program voltage Vpro greater than 0V to the wordline WL of the selected cell transistor sel_WL, that is, the bitline BL and the channel layer 150 may include lowering a threshold voltage of the selected cell transistor sel_WL by grounding OV.

In a program operation, a program voltage Vpro of about 20V or more may be applied to the wordline WL and gate electrode 185, and the bitline BL and the channel layer 150 may be grounded to 0V, such that, in the data storage layer 163 formed with a ferroelectric layer FEL, a first polarization state in which positive charges are aligned on the first side surface 163S1 adjacent to the channel layer 150 and negative charges are aligned on the second side surface 163S2 adjacent to the gate electrode 185 may be formed. By the program operation, the selected cell transistor including the data storage layer 163 may be in a programmed state.

By a program operation, in the data storage layer 163, which may be the ferroelectric layer FEL, a first polarization state in which positive charges are aligned adjacent to the channel layer 150 and negative charges are aligned adjacent to the gate electrode 185 such that a threshold voltage of the selected cell transistor sel_WL may be lowered. In this case, neighboring cells unsel_WL not programmed may maintain the gate electrode 185 in a floating state and by applying a pass voltage Vpass to the back gate electrode region BGE, the previous second polarization state may be maintained. The second polarization state may be defined as a state in which positive charges may be aligned on the second side surface 163S2, adjacent to gate electrode 185, and may be defined as a state in which negative charges are aligned on the first side surface 163S1 adjacent to channel layer 150. The pass voltage Vpass may be disposed on a level lower than a level of the program voltage Vpro and may be approximately 5V. When the gate electrode 185 of the unselected cell transistor unsel_WL may float, and when the program voltage Vpro is applied to the gate electrode 185 of the selected cell transistor sel_WL, the second polarization state of an unselected cell transistor unsel_WL may be disturbed by the high program voltage Vpro of a neighboring cell transistor. To maintain the second polarization state, the pass voltage Vpass may be applied to the back gate electrode BG to maintain the previous electric field value of the unselected cell transistor unsel_WL, and the second polarization state may not be affected and may be maintained even by the high program voltage Vpro of the neighboring gate electrode 185, which may be the same as in a read operation, and when the detection voltage is applied to the selected cell transistor sel_WL gate electrode, a read voltage may be applied to the back gate electrode BG while maintaining the gate electrode of the unselected cell transistor unsel_WL in a floating state, such that a second polarization state of the unselected cell transistor unsel_WL may be maintained and read of the unselected cell transistor sel_WL may be performed.

As illustrated in FIG. 4C, the erase operation may include simultaneously grounding the gate electrodes 185, which is a wordline, to 0V, and increasing a threshold voltage of the memory cell transistor by applying an erase voltage Vera to the channel layer 150 through the bitline BL and the source structure CSL, for example, the second substrate 200. For example, the entirety of the gate electrodes 185, the wordline WL, may be grounded, and while the back gate electrode BG floats, an erase voltage Vera of about 15V or more may be applied to the channel layer 150, such that a second polarization state in which electrons may be implanted from the gate electrode 185, the wordline, into the gate dielectric structure 160, and positive charges may be aligned adjacent to the gate electrode 185 in the data storage layer 163, which may be formed as a ferroelectric layer FEL, and negative charges may be aligned adjacent to the channel layer 150. In a programmed state, the data storage layer 163 may be a first polarization state, and by the erase operation, the polarization direction of the data storage layer 163 may be switched from the first polarization state to the second polarization state. That is, the direction of polarization of the data storage layer 163 may be switched by the program operation or the erase operation.

By the erase operation, the data storage layer 163, which may be the ferroelectric layer FEL, may simultaneously enter the second polarization state, thereby increasing a threshold voltage of the memory cell transistor MCT.

As described above, in the memory cell transistor MCT including the data storage layer 163, a memory window may be set by a difference between a threshold voltage of the memory cell transistor MCT in the programmed state and a threshold voltage of the memory cell transistor MCT in the erased state. Also, to reduce the influence of the polarization state of unselected neighboring cells by a relatively high program voltage of the selected cell, a pass voltage or a read voltage may be applied using the back gate electrode BG, and the back gate voltage may be applied simultaneously to the plurality of channel structures CH through a small number of back gate contacts 148, for example, the back gate voltage may be applied simultaneously to a plurality of channel structures in a block, or to the channel structures CH forming a row.

As described above, since the data storage layer 163 for storing data using a polarization state may be included, the memory window of the semiconductor device 100 may be increased, endurance and retention of the semiconductor device 100 may be improved and an operation voltage of the semiconductor device 100 may be lowered.

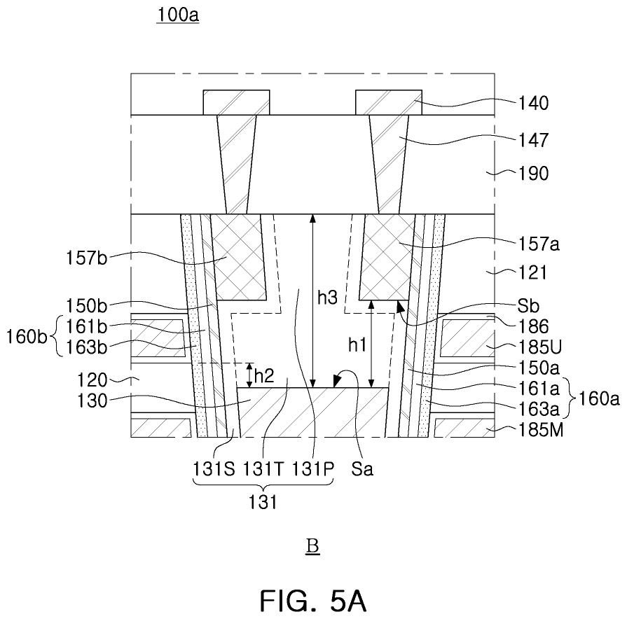

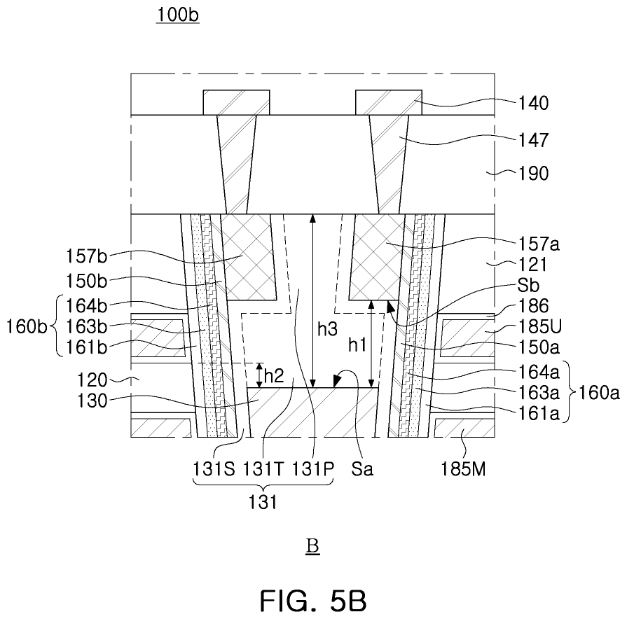

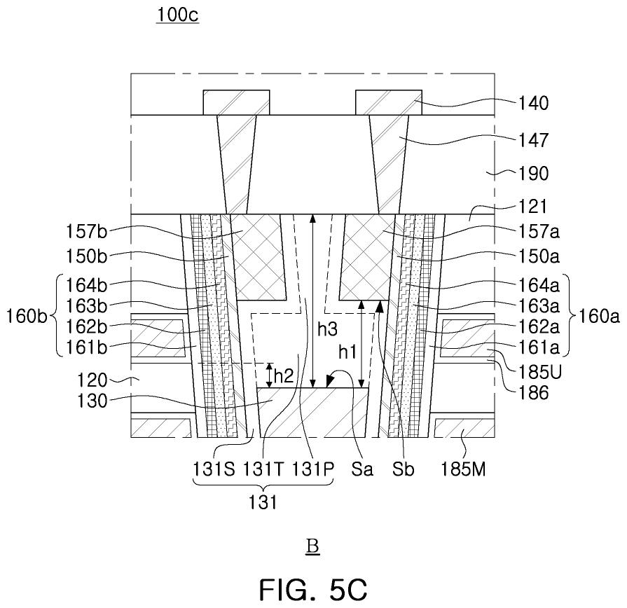

FIGS. 5A to 5C are portion enlarged diagrams schematically illustrating a semiconductor device according to example embodiments. FIGS. 5A to 5C illustrate enlarged images of the region corresponding to the ‘B’ region in FIG. 2A.

Referring to FIG. 5A, in a channel structure CH of a semiconductor device 100a, the structure of the gate dielectric structure 160 may be different from the example embodiment in FIGS. 1 to 3B. The gate dielectric structure 160 may be the same as the structure in FIGS. 1 to 3B other than the configuration in which positions of the second insulating layer 161 and the data storage layer 163 are switched.

Specifically, the second insulating layer 161 may be disposed by surrounding an external side surface of the channel layer 150, and the data storage layer 163 including a ferroelectric layer may be disposed by surrounding the external side surface of the second insulating layer 161.

Referring to FIG. 5B, in the channel structure CH of the semiconductor device 100b, the structure of the gate dielectric structure 160 may be different from the example embodiment in FIGS. 1 to 3B.

The gate dielectric structure 160 may further include an interfacial insulating layer 164 between the channel layer 150 and the data storage layer 163. The interfacial insulating layer 164 may include at least one of silicon oxide, SiON, AlON, and a high-κ dielectric. The high-κ dielectric may be a dielectric having a dielectric constant higher than that of silicon oxide.

Accordingly, in each of the channel portions CP1 and CP2, a gate electrode 185, a second insulating layer 161, a data storage layer 163, an interfacial insulating layer 164, a channel layer 150, a first insulating layer 131 and a back gate electrode region BGE may overlap each other.

Referring to FIG. 5C, in the channel structure CH of the semiconductor device 100c, a structure of the gate dielectric structure 160 may be different from the example embodiment in FIG. 5B.

The gate dielectric structure 160 may further include a trap layer 162 between the second insulating layer 161 and the data storage layer 163. The trap layer 162 may be configured as a different material from the material of the data storage layer 163.

The trap layer 162 may be configured as a charge trap layer storing data using a charge trap. The trap layer 162 may include at least one of SiO, SiN, SiON, SiO/SiN, SiO/SiON, SiO/AlO, SiO/HfO, SiO/SiN/SiO or SiO/nano-crystal, which may store data using a charge trap. Here, terms such as SiO/SiN may refer to stack structures of the SiN material layer and the SiO material layer. The trap layer 162 may include at least one of Si(O)N, (Hf, Zr, Al, C, N, Gd, Y, Ti, La, Ta)-doped Si(O)N, or HfO₂.

Accordingly, in each of the channel portions CP1 and CP2, a gate electrode 185, a second insulating layer 161, a trap layer 162, a data storage layer 163, an interfacial insulating layer 164, a channel layer 150, a first insulating layer 131 and a back gate electrode region BGE may overlap each other.

The semiconductor device 100 may further include a floating gate electrode at a position of the trap layer 162, but an example embodiment thereof is not limited thereto. Also, when the trap layer 162 is included, a memory device may be implemented only with the trap layer 162 without the data storage layer 163 including the ferroelectric layer. In other words, a memory device may be implemented with a layered structure including the gate electrode 185, the second insulating layer 161, the trap layer 162, the interfacial insulating layer 164, the channel layer 150, the first insulating layer 131 and the back gate electrode region BGE in each of the channel portions CP1 and CP2, but an example embodiment thereof is not limited thereto.

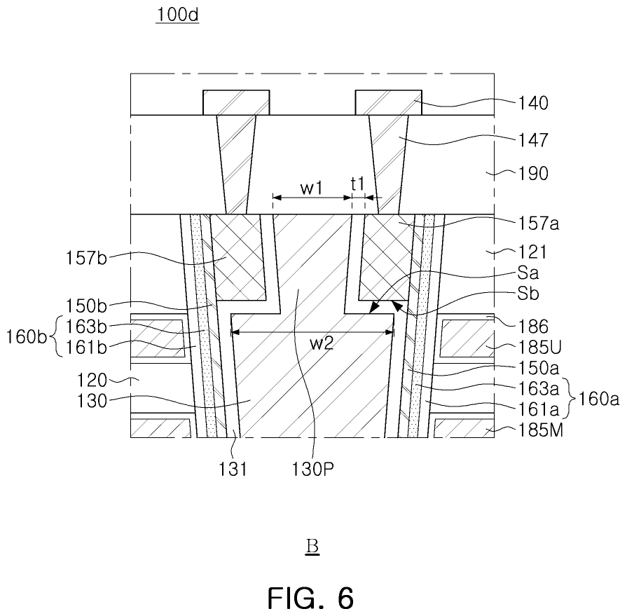

Hereinafter, example embodiments will be described with reference to FIGS. 6 to 12.

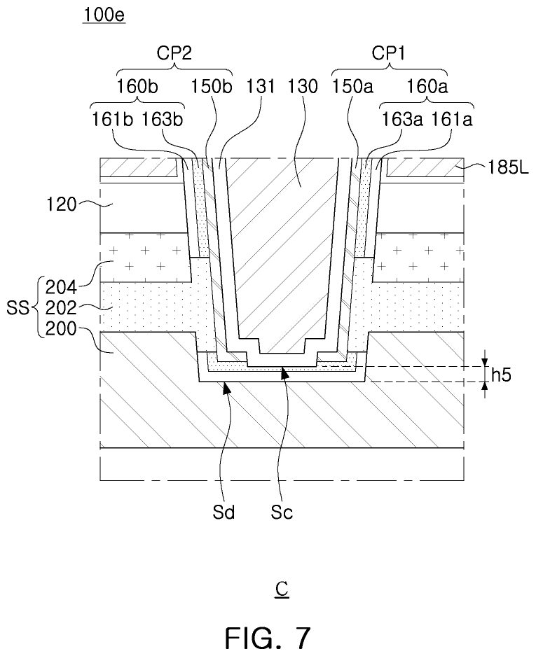

FIGS. 6 and 7 are schematic cross-sectional diagrams illustrating a semiconductor device according to example embodiments. FIG. 6 illustrates a region corresponding to region “B” in FIG. 2A, and FIG. 7 illustrates a region corresponding to region “C”.

Referring to FIG. 6, a semiconductor device 100d may be the same as an example embodiment in FIGS. 1A to 3B other than the configuration in which the back gate structure BGS is exposed to the channel upper surface in the channel structure CH.

Specifically, in the back gate structure BGS of the semiconductor device 100d, an upper surface of the back gate electrode region BGE may extend upwardly, with the first portion 131S of the first insulating layer 131 having the first thickness t1 being interposed between the back gate electrode region BGE and a lower surface Sb of the pad pattern 157a and 157b. For example, the upper surface Sa of the back gate electrode region BGE may be disposed on a level higher than the level of the lower surface of the upper gate electrode 185U.

The back gate electrode region BGE may further include a back gate protrusion 130P protruding from the upper surface Sa to a spacing between pad patterns 157a and 157b. The back gate protrusion 130P may protrude from the upper surface of the channel structure CH to be coplanar with the upper surface of the pad patterns 157a and 157b. The first insulating layer 131 may conformally cover a side surface of the conductive material layer 130, including the back gate protrusion 130P. The portion of the first insulating layer 131 interposed between the back gate protrusion 130P and both side surfaces of the pad patterns 157a and 157b may have the first thickness t1.

The upper surface width W1 of the back gate protrusion 130P may be smaller than the upper surface width W2 of the back gate electrode region BGE, and the upper surface width W1 of the back gate protrusion 130P may be equal to the width W1 of the back gate line region BGL. Accordingly, the line region BGL having the same width as that of the back gate protrusion 130P may extend outwardly of the channel structure CH. The first insulating layer 131 having the same first thickness t1 may be disposed on the entire side surface and the bottom surface of the back gate structure BGS, including the protrusion 130P. The first thickness t1 of the first insulating layer 131 may be the same in regions between protrusion 130P and the side surfaces of pad patterns 157a and 157b, between the upper surface Sa of the back gate electrode region BGE and the lower surface Sb of pad patterns 157a and 157b and between back gate electrode region BGE and channel layers 150a and 150b, and may conformally cover the channel hole in which the pad patterns 157a and 157b are formed. Accordingly, differently from FIG. 2A, the first portion 131S and the second portion 131T of the first insulating layer 131 may not be disposed separately. For example, the first insulating layer 131 may extend to have the same thickness from a lower portion to an upper portion of the channel hole.

When the back gate structure BGS is disposed on the same level as a level of an upper surface of the channel structure CH, a plug for the back gate contact 148 may be disposed in a layer on an end of the back gate line region BGL, and may be connected to the back gate interconnection 145.

Referring to FIG. 7, the semiconductor device 100e may be the same as an example embodiment in FIG. 3B other than the configuration in which the lower surface Sc of the first insulating layer 131 of the lower end of the back gate structure BGS is disposed on a level higher than a level of the lower surface Sd of the channel structure CH.

Specifically, the first insulating layer 131 may not be disposed to protrude externally of the lower surface Sd on a lower end of the back gate structure BGS of the semiconductor device 100e, and the lower surface Sc may be disposed on a level higher than a level of the lower surface Sd of the channel structure CH.

The first insulating layer 131 surrounding the back gate structure BGS may cut (e.g., extend through) the channel layer 150 on the lower surface Sd of the channel structure CH, and the lower surface Sc of the first insulating layer 131 may be disposed on a level lower than a level of the lower surface of channel layer 150. That is, the back gate structure BGS may extend in the Z-direction to the level on which the channel layer 150 may be cut by the first insulating layer 131, and the lower surface Sc of the first insulating layer 131 may be disposed on a level on which the first insulating layer 131 may partially protrude into the gate dielectric structure 160 to not completely cut the gate dielectric structure 160, and for example, the lower surface Sc of the first insulating layer 131 may protrude up to a portion of the charge storage layer 163, but an example embodiment thereof is not limited thereto. For example, the lower surface Sc of the first insulating layer 131 may protrude up to a portion of the second insulating layer 161, and the lower surface Sd of the channel structure CH and the lower surface Sc of the first insulating layer 131 may be coplanar with each other. The back gate structure BGS disposed in the first insulating layer 131 may have a lower surface disposed on a level higher than the level of the lower surface Sc of the first insulating layer 131, such that the back gate structure BGS may not be disposed on a level lower than the lower surface Sd of the channel structure CH.

Preferably, a distance h5 between the lower surface Sd of the channel structure CH and the lower surface Sc of the first insulating layer 131 may have a value greater than a thickness of the second insulating layer 161 such that the first insulating layer 131 may not meet the second insulating layer 161. In other words, when the memory cell region, which is the first region CELL, may be arranged in reverse phase and the source structure SS may be disposed in an upper portion, exposure of the back gate electrode region BGE may be prevented while the channel layer 150 is exposed by having a level on which the first insulating layer 131 cuts the channel layer 150 and partially protrudes into the charge storage layer 163.

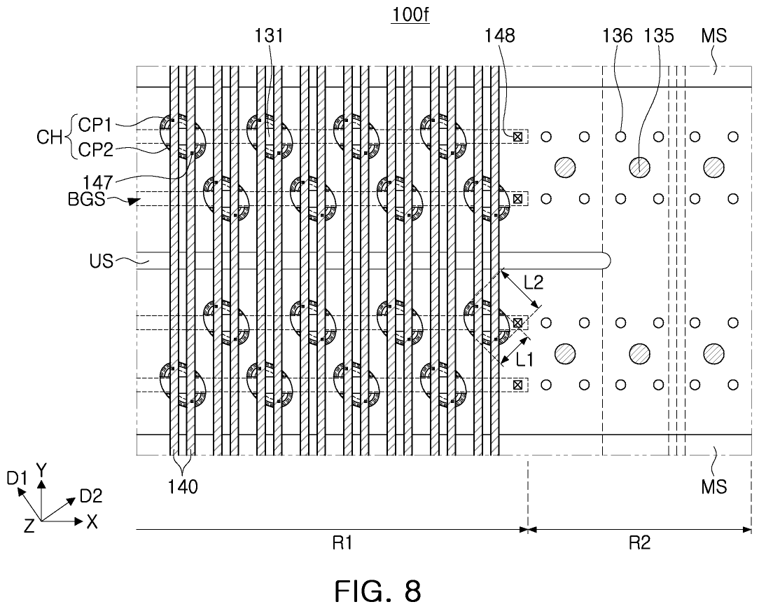

FIGS. 8 to 11 are diagrams illustrating a semiconductor device according to example embodiments, viewed from above.

Referring to FIG. 8, a semiconductor device 100f may be the same as an example embodiment in FIG. 3B other than configuration in which the channel structures CH have an oval shape, elongated shape, quadrangular shape, or rounded quadrangular shape extending in the D1 direction inclined in the X-direction and Y-direction.

Channel structures CH may be disposed to form a grid pattern on a X-Y plane or may be disposed to form a zigzag pattern in one direction. The channel structures CH may have a pillar shape filling the channel hole, and may have an inclined side surface such that a width may decrease toward the second substrate 200 depending on an aspect ratio.

In the channel structures CH, a long-direction length L2 in the D1 direction may be greater than a short-direction length L1 in the D2 direction perpendicular to the D1 direction. The long-direction length L2 may range, for example, from about 80 nm to about 200 nm, but an example embodiment thereof is not limited thereto, and may be determined depending on a pitch of the bitlines 140 to 180.

Each of the channel structures CH may be divided into first and second channel portions CP1 and CP2 by the back gate structure BGS penetrating a center in the Z direction and extending in the X-direction. The back gate electrode region BGE of the back gate structure BGS may have an oval shape extending in the D1 direction along the shape of the channel structure CH, the back gate line region BGL may extend in the X-direction, and may connect the back gate electrode regions BGE in the neighboring channel structure CH to each other. Each of the first and second channel portions CP1 and CP2 may form a memory cell string. Each of the first and second channel portions CP1 and CP2 may have, for example, a hemi-cylinder shape or a semi-pillar shape corresponding to half of an elliptical pillar. The first channel portion CP1 may have a shape in which the second channel portion CP2 rotates by 180 degrees.

As the channel structures CH extend in the D1 direction inclined in the X-direction and Y-direction, the channel structures CH may overlap such that a spacing distance between the channel structures CH may decrease.

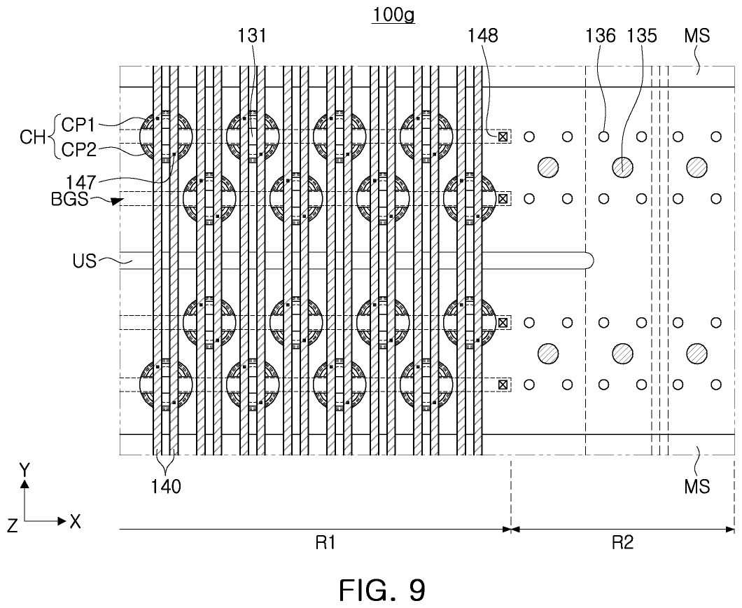

Referring to FIG. 9, a semiconductor device 100g may be the same as an example embodiment in FIGS. 1A to 3B other than the configuration in which the channel structures CH have a circular shape having the same diameter in the X-direction and Y-direction.

The diameter of the channel structure CH may be 2 to 3 times greater than the pitch of the bitlines 140, and may be arranged in a zigzag pattern.

Each of the channel structures CH may be divided into first and second channel portions CP1 and CP2 by the back gate structure BGS penetrating a circular center in the Z-direction and extending in the X-direction. The back gate electrode region BGE of the back gate structure BGS may have a circular shape along the shape of the channel structure CH, the back gate line region BGL may extend in the X-direction and may connect the back gate electrode regions BGE in adjacent channel structures to each other. Each of the first and second channel portions CP1 and CP2 may have, for example, a hemi-cylindrical shape or a semi-pillar shape corresponding to half of a circular pillar. The first channel portion CP1 may have a shape in which the second channel portion CP2 rotates by 180 degrees. The channel structures CH may be formed in a circular shape having a large diameter such that the first channel portion CP1 and the second channel portion CP2 may have a channel layer 150 having a sufficiently long length to form a memory cell.

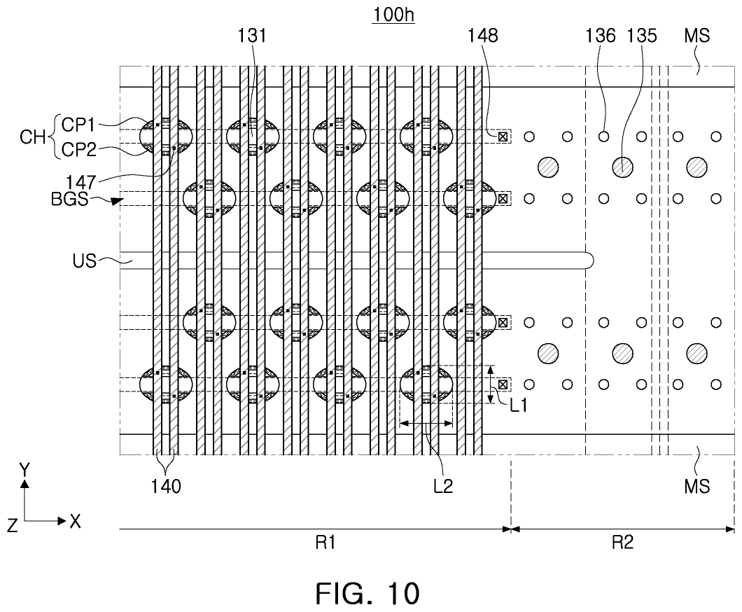

Referring to FIG. 10, a semiconductor device 100h may be the same as an example embodiment in FIGS. 1A to 3B, other than the configuration in which the channel structures CH may have an oval shape, elongated shape, quadrangular shape, or rounded quadrangular shape extending in the X-direction. That is, each of the channel structures CH may have a shape obtained by rotating the channel structure CH in FIGS. 1A to 3B by 90 degrees.

A long-direction length L2 in the X-direction of the channel structure CH may be larger than a short-direction length L1 in the Y-direction, and the long-direction length L2 may range, for example, from about 80 nm to about 200 nm, but an example embodiment thereof is not limited thereto, and the lengths may be determined depending on the pitch of the bitlines 140.

When the channel structure CH has a longitudinal length L2 in a direction perpendicular to the extension direction of bitlines 140, the pitch of bitlines 140 may be sufficiently ensured, and the contact 147 between the isolated first channel portion CP1 and the second channel portion CP2 may be formed stably.

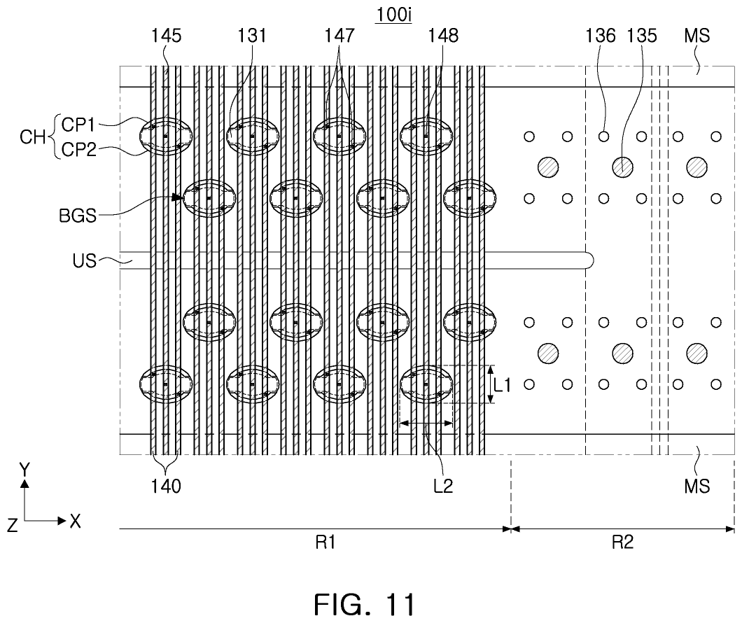

Referring to FIG. 11, a semiconductor device 100i may be the same as the semiconductor device 100h in FIG. 10 other than the configuration in which the back gate structure BGS is disposed only in the channel structure CH, the back gate contact 148 is disposed between bitline 140 and contact plug 147, and the back gate interconnection 145 is disposed between bitlines 140.

Specifically, the back gate structure BGS may extend in the X-direction in the channel structure CH, and may be disposed to divide the channel structure CH into two portions, a first channel portion CP1 and a second channel portion CP2. Accordingly, the back gate structure BGS may include only the back gate electrode region BGE without the back gate line region BGL connecting the back gate electrode region BGE between neighboring channel structures CH. In this case, the back gate interconnection 145 may be disposed between two bitlines 140 passing over the channel structure CH. Accordingly, the back gate contact 148 may be disposed above the back gate electrode region BGE in the channel structure CH and may be connected to the back gate interconnection 145. When the channel structure CH has a large size such that the channel structure CH may be divided into two channel portions CP1 and CP2 by the internal back gate electrode region BGE, the back gate contact 148 may be formed in the channel structure CH, such that cutting may not be performed. The first insulating layer 131 may be conformally disposed by surrounding the back gate structure BGS. The back gate structure BGS may extend in the Y-direction and may be divided into two channel portions CP1 and CP2. The back gate structure BGS may have an extended width in a central region of the channel structure CH to ensure a length of the channel layer 150, and may have a line shape in a circumferential portion. Accordingly, the back gate voltage may be provided in common to two channel portions CP1 and CP2 divided by implementing the back gate electrode region BGE without a filling insulating layer in the channel structure CH.

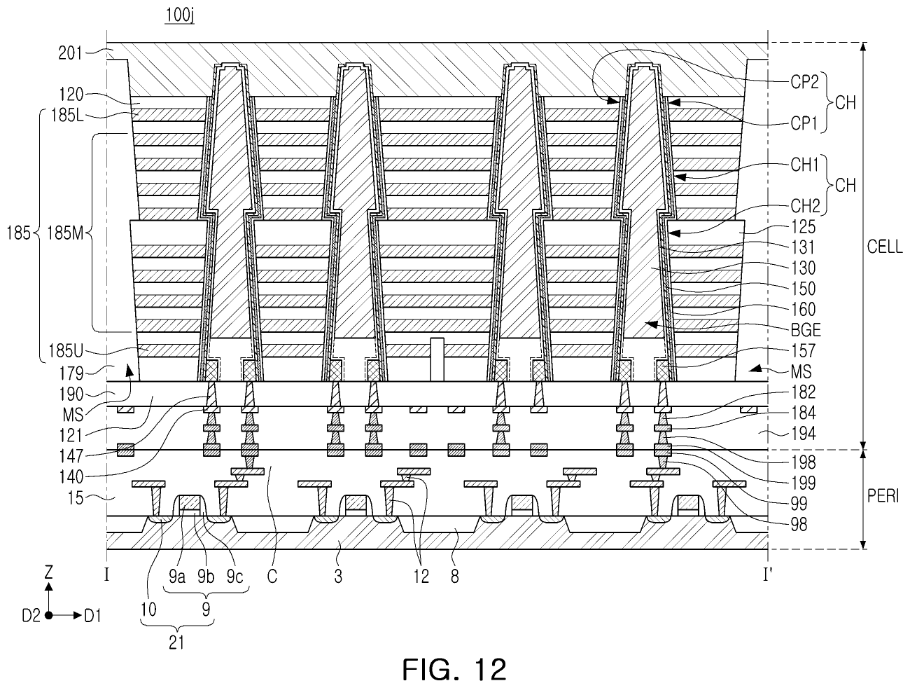

Referring to FIG. 12, the semiconductor device 100j may include a first semiconductor structure S1 and a second semiconductor structure S2 bonded to each other using a wafer bonding method.

The description of the peripheral circuit region PERI described above with reference to FIGS. 1A to 3B may be applied to the first semiconductor structure S1. However, the first semiconductor structure S1 may further include first bonding vias 98 and first bonding pads 99, which may be bonding structures. The first bonding vias 98 may be disposed on the uppermost circuit interconnection lines 12 and may be connected to the circuit interconnection lines 12. At least a portion of the first bonding pads 99 may be connected to the first bonding vias 98 on the first bonding vias 98. The first bonding pads 99 may be connected to the second bonding pads 199 of the second semiconductor structure S2. The first bonding pads 99 may provide, together with the second bonding pads 199, an electrical connection path according to bonding between the first semiconductor structure S1 and the second semiconductor structure S2. The first bonding vias 98 and the first bonding pads 99 may include a conductive material, for example, copper (Cu).

The description of the memory cell region CELL described with reference to FIGS. 1A to 3B may be applied to the second semiconductor structure S2, if otherwise indicated. The second semiconductor structure S2 may further include lower contact plugs 182 and lower interconnection lines 184, which may be an interconnection structure, and may further include second bonding vias 198 and second bonding pads 199, which may be bonding structures. The second semiconductor structure S2 may further include a passivation layer (not illustrated) covering an upper surface of the plate layer 201.

The lower contact plugs 182 may be disposed below the upper interconnection structure including bitlines 140 and back gate interconnections 145, and may connect the upper interconnection structure to the lower interconnection lines 184. However, in example embodiments, the number of layers of the contact plugs and the interconnection lines forming the interconnection structure and the arrangement form thereof may be varied. The lower contact plugs 182 and the lower interconnection lines 184 may be formed of a conductive material and may include at least one of tungsten (W), aluminum (Al), and copper (Cu), for example.

The second bonding vias 198 and the second bonding pads 199 may be disposed below the lowermost lower interconnection lines 184. The second bonding vias 198 may be connected to the upper interconnection structure and the second bonding pads 199, and the second bonding pads 199 may be bonded to the first bonding pads 99 of the first semiconductor structure S1. The second bonding vias 198 and the second bonding pads 199 may include a conductive material, for example, copper (Cu).

The first semiconductor structure S1 and the second semiconductor structure S2 may be bonded to each other by copper (Cu)-copper (Cu) bonding by the first bonding pads 99 and the second bonding pads 199. In addition to copper (Cu)-copper (Cu) bonding, the first semiconductor structure S1 and the second semiconductor structure S2 may be further bonded to each other by dielectric-dielectric bonding. The dielectric-dielectric bonding may be bonding by dielectric layers forming a portion of each of the lower capping layer 15 and the cell region insulating layer 194 and surrounding the first bonding pads 99 and the second bonding pads 199. Accordingly, the first semiconductor structure S1 and the second semiconductor structure S2 may be bonded to each other without an adhesive layer.

The passivation layer may be disposed on an upper surface of the plate layer 201 and may protect the semiconductor device 100j. The passivation layer may include at least one of an insulating material, for example, silicon oxide, silicon nitride, and silicon carbide, and may include a plurality of insulating layers in example embodiments.

In the example embodiment, the second semiconductor structure S2 may not include the first and second horizontal conductive layers 102 and 104 (see FIG. 2). The channel structures CH may be directly connected to the plate layer 201 in a state in which the channel layers 150 are exposed through the upper end. In this case, the channel layers 150a and 150b of the two separated channel portions CP1 and CP2 may be directly connected to the plate layer 201 in a separated manner. In this case, the first insulating layer 131 may be disposed between the back gate structure BGS and plate layer 201 and may prevent short circuit between the back gate structure BGS and plate layer 201. Accordingly, an upper surface of first insulating layer 131 may be disposed on the same or higher level than a level of an upper surface of channel layers 150a and 150b. However, the electrical connection between the channel structures CH and the common source line may vary in example embodiments, and the channel structures CH and the source structures SS may also have the same structure as in the example embodiment in FIGS. 2A to 2B.

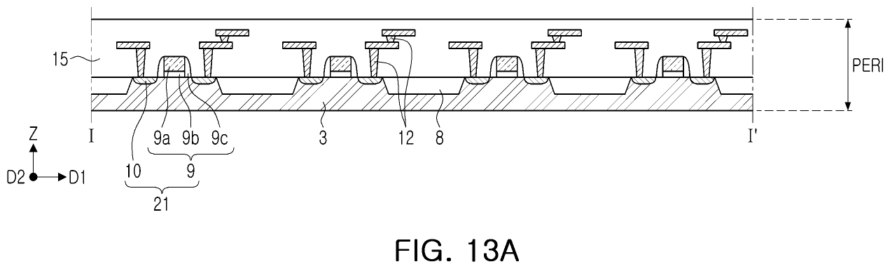

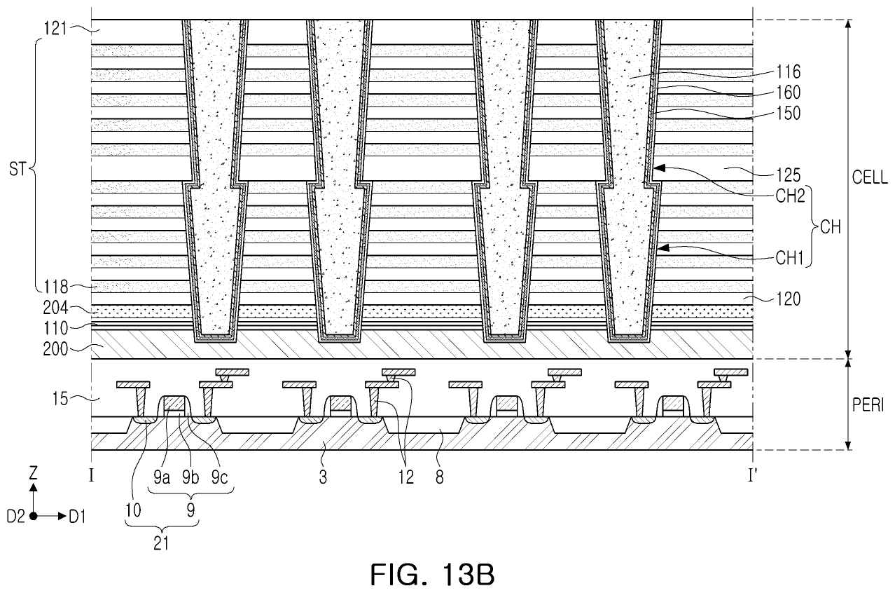

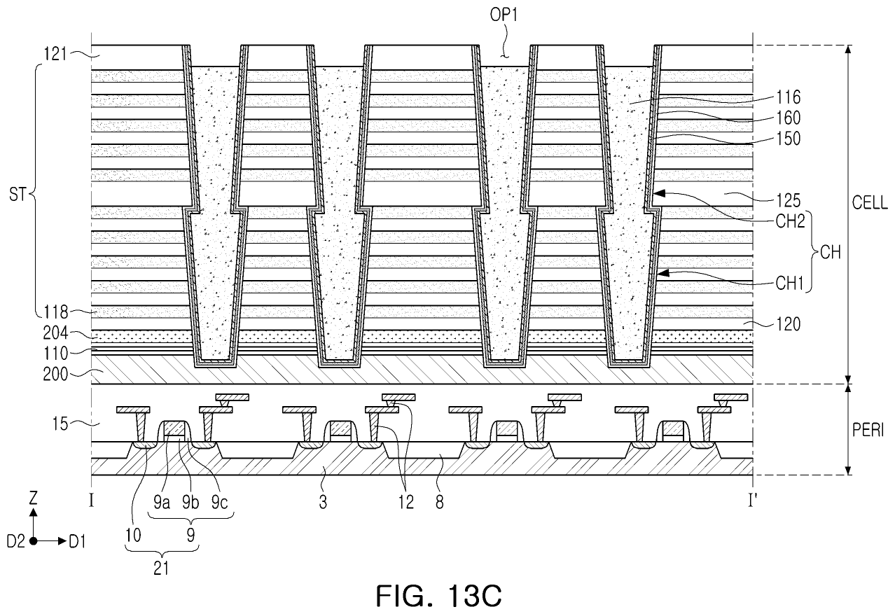

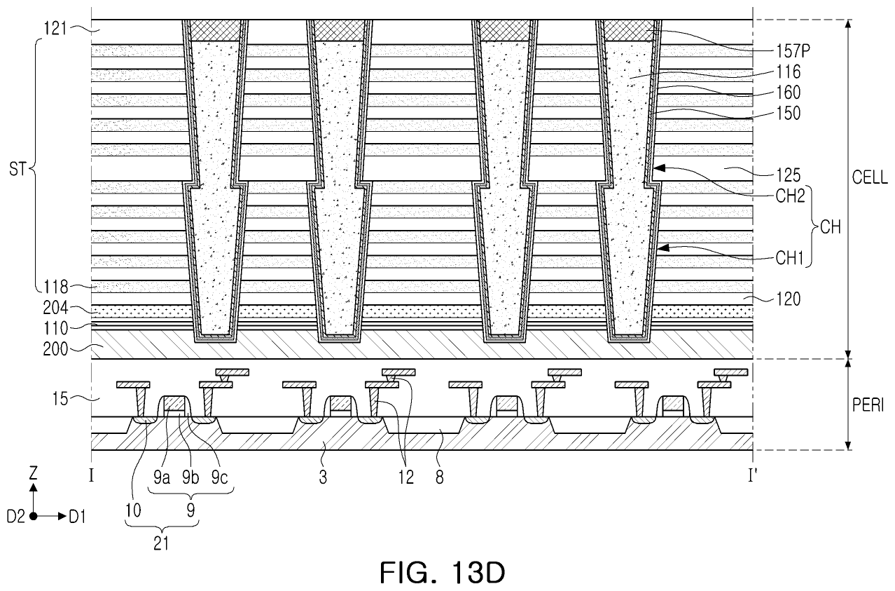

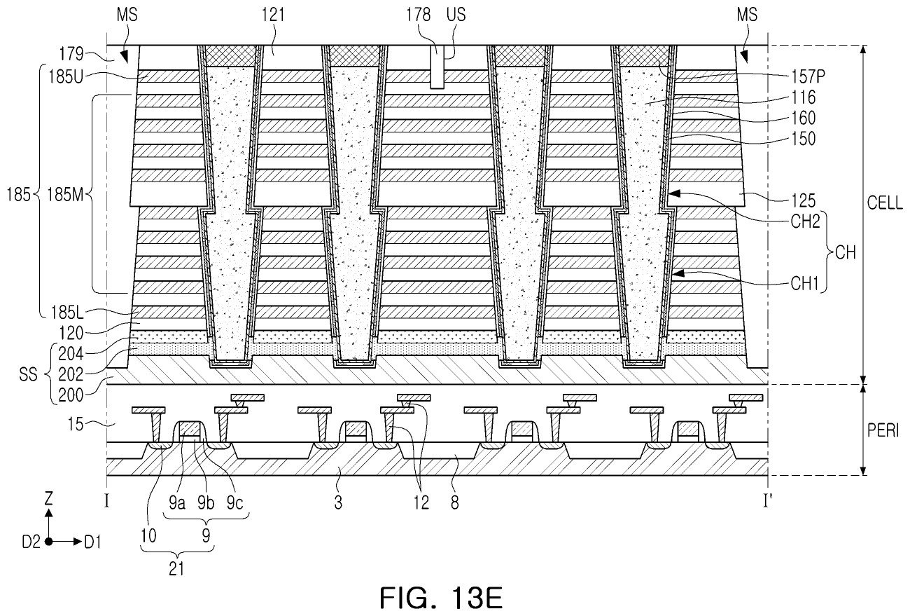

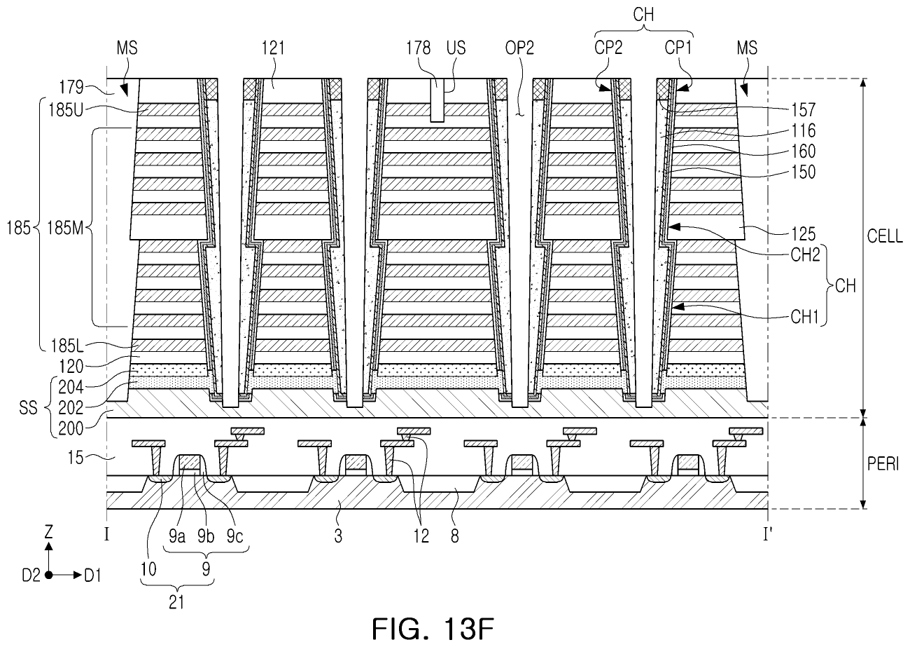

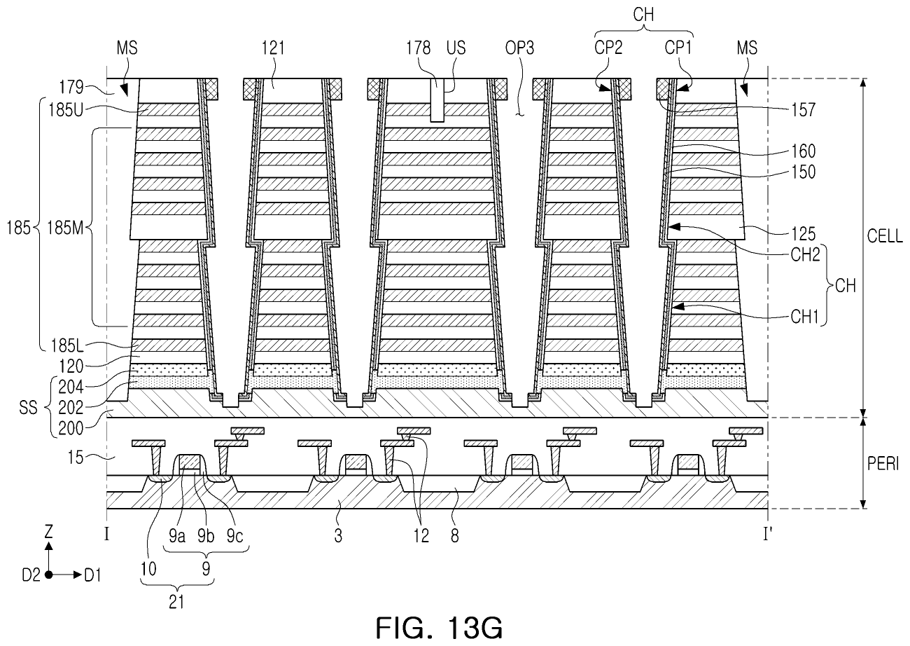

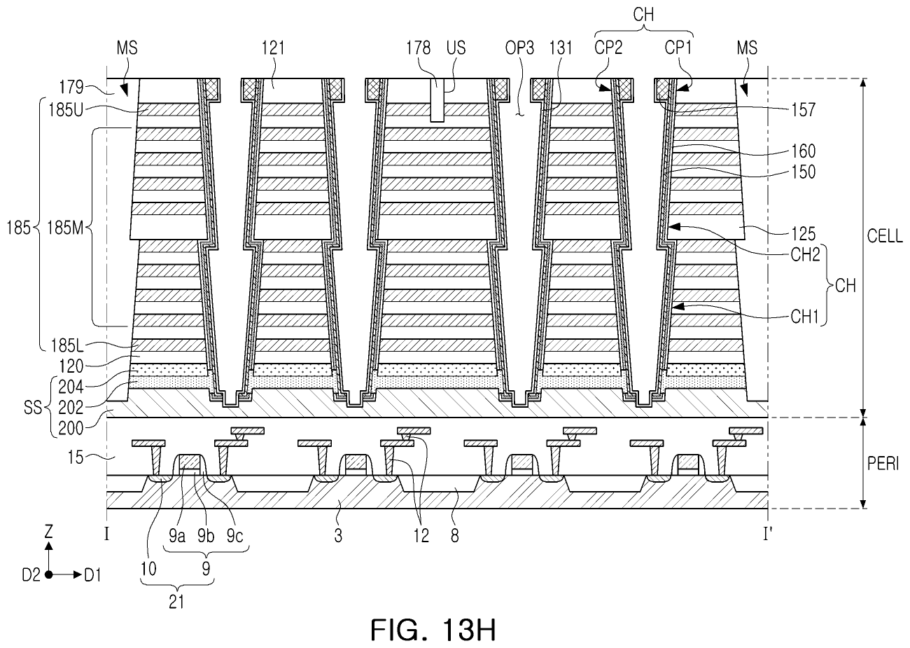

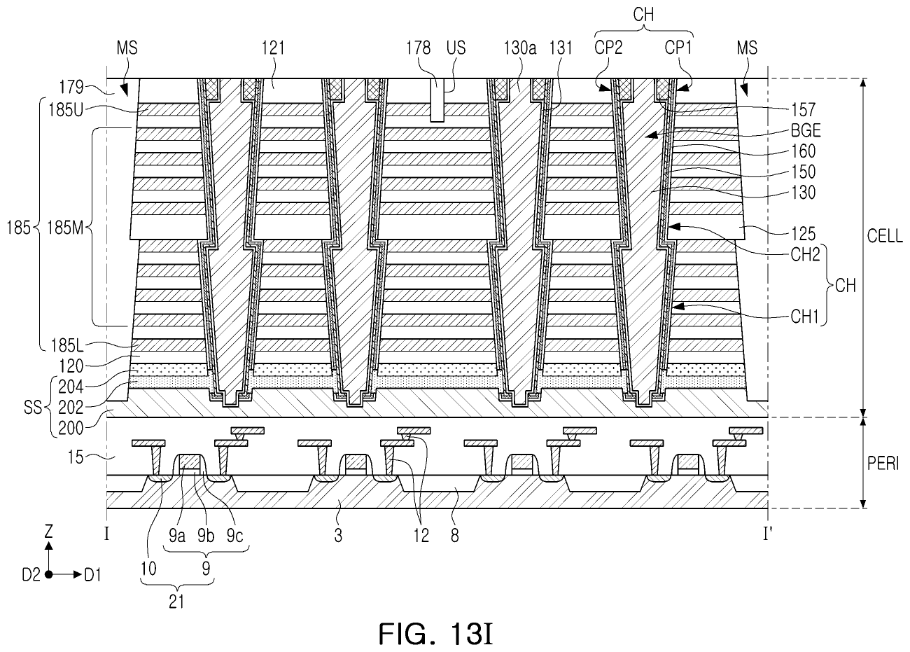

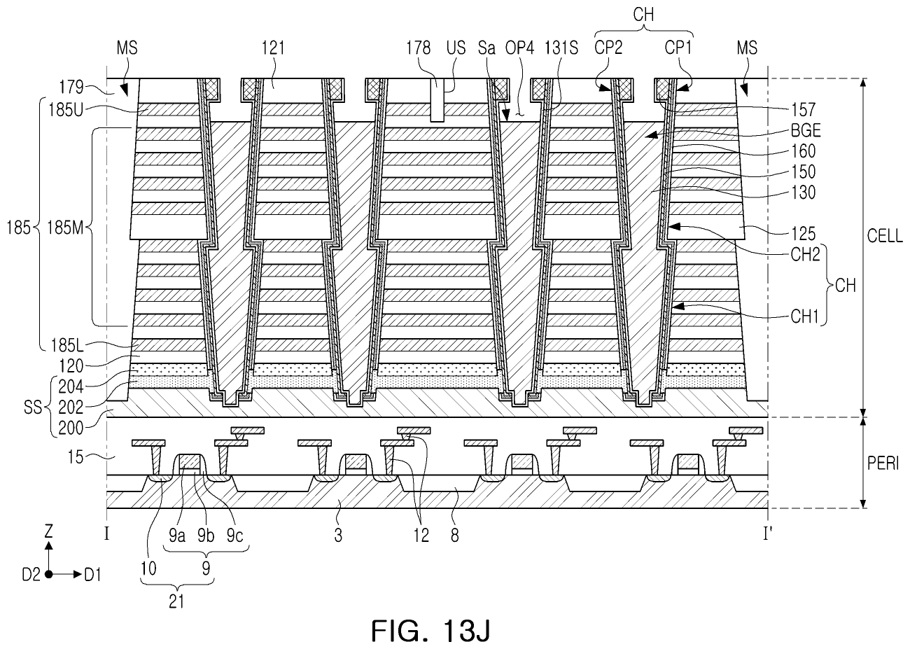

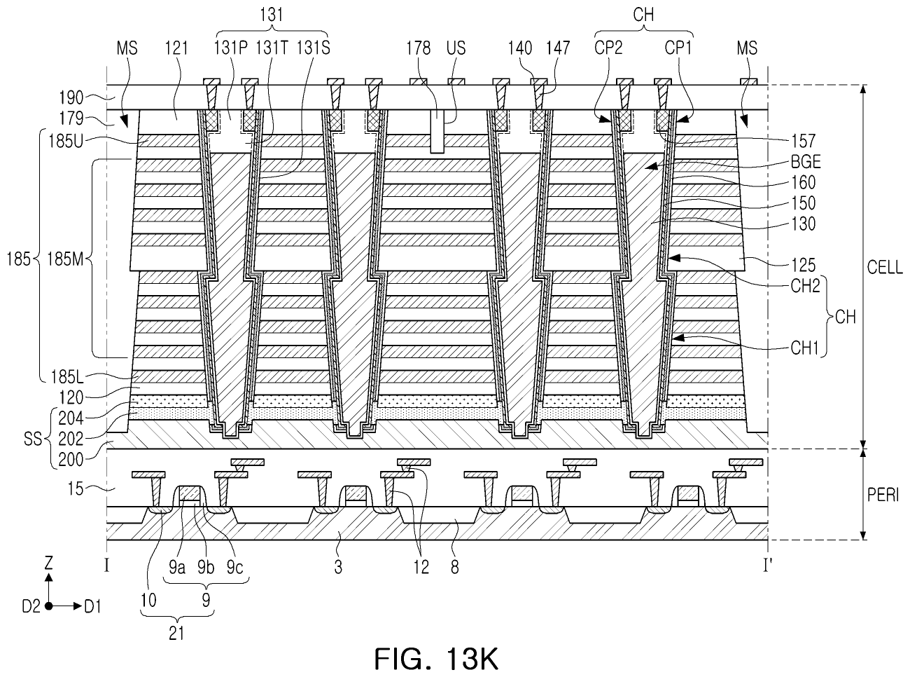

In the description below, an example of a method of manufacturing the semiconductor device 100 according to an example embodiment will be described with reference to FIGS. 13A to 13K. FIGS. 13A to 13K are cross-sectional diagrams illustrating a region corresponding to FIG. 2A, illustrating an example of a method of manufacturing a semiconductor device according to an example embodiment.

Referring to FIG. 13A, circuit devices 21, a lower interconnection structure 12, a lower bonding structure 18, and a lower capping layer 15 forming the second region PERI may be formed on a first substrate 3.

First, device isolation layers 8 may be formed in the first substrate 3, and a circuit gate dielectric layer 9b and a circuit gate electrode 9a may be formed in order on the first substrate 3. The device isolation layers 8 may be formed, for example, by a shallow trench isolation (STI) process. The circuit gate dielectric layer 9b may be formed on the first substrate 3, and the circuit gate electrode 9a may be formed on the circuit gate dielectric layer 9b. The circuit gate dielectric layer 9b and the circuit gate electrode 9a may be formed using atomic layer deposition (ALD) or chemical vapor deposition (CVD). The circuit gate dielectric layer 9b may be formed of silicon oxide, and the circuit gate electrode 9a may be formed of at least one of polycrystalline silicon or a metal silicide layer, but an example embodiment thereof is not limited thereto. Thereafter, spacer layers 9c may be formed on walls of both sides of the circuit gate dielectric layer 9b and the circuit gate electrode 9a, and impurities may be injected into the active region of the first substrate 3 on both sides of the circuit gate electrode 9a, thereby forming source/drain regions 10.

Among the lower interconnection structure 12, the lower contact plugs may be formed by forming a portion of the lower capping layer 15, removing a portion thereof by etching, and filling a conductive material therein. Lower interconnection lines may be formed, for example, by depositing a conductive material and patterning the material.

The lower capping layer 15 may include a plurality of insulating layers. The lower capping layer 15 may become a portion of the lower interconnection structure 12 in each process of forming the lower interconnection structure 12. Accordingly, a second region PERI may be formed.

Referring to FIG. 13B, a second substrate 200 may be formed on the second region PERI, and a stack structure and channel structures CH may be formed on the second substrate 200. The second substrate 200 may include a semiconductor material, such as a group IV semiconductor, a group III-V compound semiconductor, or a group II-VI compound semiconductor.

The horizontal sacrificial structure 110 may be formed on the second substrate 200, and the sacrificial insulating layer 118 and the interlayer insulating layer 120 may be formed. The horizontal sacrificial structure 110 may be formed by stacking the first horizontal sacrificial layers and the second horizontal sacrificial layer consecutively. A lower stack structure may be formed by alternately stacking the sacrificial insulating layers 118 and the interlayer insulating layers 120 on the horizontal sacrificial structure 110, and an upper stack structure may be formed by alternately stacking the sacrificial insulating layers 118 and the interlayer insulating layers 120. The channel structures CH penetrating the stack structure of the sacrificial insulating layers 118 and the interlayer insulating layers 220 may be formed. In a region corresponding to the separation region MS (see FIG. 2B), a separation opening (not illustrated) penetrating the stack structure of the sacrificial insulating layers 118 and the interlayer insulating layers 120 may be formed together. The sacrificial insulating layers 118 may be partially replaced with the gate electrodes 185 through a subsequent process.

Vertical sacrificial structures may be formed to penetrate the lower stack structure. The vertical sacrificial structures may be formed by anisotropically etching the lower stack structure of the sacrificial insulating layers and the interlayer insulating layers 120 using a mask layer, and may be formed by forming hole-shaped lower channel holes and filling the holes. The vertical sacrificial structure may include a semiconductor material such as polycrystalline silicon. According to an example embodiment, the vertical sacrificial structure may include at least one of silicon oxide, silicon nitride, and silicon oxynitride. After the vertical sacrificial structure is formed, an upper stack structure of the sacrificial insulating layers 118 and the interlayer insulating layers 120 may be formed on the lower stack structure and the vertical sacrificial structure.

Thereafter, an upper interlayer insulating layer 121 covering the stack structure of the sacrificial insulating layers 118 and the interlayer insulating layers 120 may be formed.

The channel structures CH may be formed by forming upper holes on the vertical sacrificial structure, forming hole-shaped channel holes by removing the vertical sacrificial structure, and filling the channel holes with a plurality of layers. As described above, the plurality of layers may be formed by forming a gate dielectric structure 160 and a channel layer 150, and filling the channel sacrificial layer 116 therein. The upper channel holes of the channel holes may be formed by anisotropically etching the upper stack structure of the sacrificial insulating layers 118 and the interlayer insulating layers 120 using a separate mask layer. The lower channel holes of the channel holes may be formed by removing the vertical sacrificial structure exposed through the upper channel holes.

Due to a height of the stack structure, sidewalls of the channel structures CH may not be perpendicular to an upper surface of the second substrate 200. The channel holes may be formed to be recessed into a portion of the second substrate 200.

The gate dielectric structure 160 may be formed as a multilayer structure, as illustrated in FIGS. 3A and 3B. As an example, the second insulating layer 161 and the data storage layer 163 may be stacked the channel hole in order. The layers forming the gate dielectric structure 160 may extend conformally along internal sidewalls and bottom surfaces of the channel holes (CHH) to have a uniform thickness using an atomic layer deposition (ALD) or chemical vapor deposition (CVD) process.

The channel layer 150 may be formed on the gate dielectric structure 160 in the channel structures CH. The channel layer 150 may be formed to extend conformally on the gate dielectric structure 160. The channel sacrificial layer 116 may be filled with a material having etch selectivity with the channel layer 150 and the interlayer insulating layer 112, and may include at least one of silicon nitride and silicon oxynitride. The channel sacrificial layer 116 may be formed to fill the channel holes.

Referring to FIG. 13C, a first opening portion OP1 may be formed by opening an upper portion of the channel sacrificial layer 116. An etch-back process may be performed such that an upper surface of the channel structure CH may be etched to a predetermined depth, for example, the length of pad patterns 157a and 157b. In this case, since the channel sacrificial layer 116 has etching selectivity with the upper interlayer insulating layer 121 and the channel layer 150, only the channel sacrificial layer 116 in the channel hole may be etched to a predetermined depth without a mask, thereby forming the first opening portion OP1.

As illustrated in FIG. 13D, a pad pattern layer 157P may be formed by filling the first opening portion OP1. The pad pattern layer 157P may be formed by filling the first opening portion OP1, forming the pad pattern layer 157P to cover an upper portion of the upper interlayer insulating layer 121, and flattening the layer until the upper interlayer insulating layer 121 is exposed. The pad pattern layer 157P may form pad patterns 157a and 157b, and may include doped polycrystalline silicon.

Referring to FIG. 13E, gate electrodes 185 may be formed by removing the sacrificial insulating layers 118 the separation opening and filling a conductive material therein. A separation region MS may be formed by filling the separation opening with a separation insulating layer 179. In this case, the first horizontal conductive layer 102 may be formed preferentially through the separation opening, and the sacrificial insulating layers 118 may be removed.

The separation opening may be formed to penetrate the stack structure of the sacrificial insulating layers 118 and the interlayer insulating layers 120, to penetrate the second horizontal conductive layer 104 in a lower portion, and to extend in the X-direction. Thereafter, sacrificial spacer layers may be formed in a separation opening and the second horizontal sacrificial layer may be exposed by the etch-back process. The exposed second horizontal sacrificial layer may be selectively removed, and the upper and lower first horizontal sacrificial layers may be removed. The horizontal sacrificial structure 110 may be removed, for example, by a wet etching process. During the process of removing the horizontal sacrificial structure 110, a portion of the gate dielectric structure 160 exposed in the region from which the second horizontal sacrificial layer is removed may also be removed, thereby forming a contact region in which the external side surface of the channel layer 150 is exposed.

Thereafter, the first horizontal conductive layer 102 may be formed by depositing a conductive material in a region from which the horizontal sacrificial structure 110 is removed, and the sacrificial spacer layers may be removed in the separation opening.

Thereafter, the sacrificial insulating layers 118 may be selectively removed with respect to the interlayer insulating layers 120, for example, using wet etching. Accordingly, a plurality of tunnel portions may be formed between the interlayer insulating layers 120.

Gate electrodes 185 may be formed by depositing a conductive material on the plurality of tunnel portions. The conductive material may include a metal, polycrystalline silicon, or a metal silicide material. After the gate electrodes 185 are formed, the conductive material deposited in the separation opening may be removed through an additional process, a separation region MS may be formed by filling an insulating material and a conductive material, and an upper separation region US may also be formed.

Referring to FIG. 13F, cell separation openings OP2 penetrating the channel structures CH may be formed.

First, cell separation openings OP2 penetrating the channel structures CH and extending in the X-direction may be formed on the channel structures CH. Each of the cell separation openings OP2 may extend in the Z-direction from an upper end of the channel structure CH to a level on which the channel layer 150 on a lower end may be cut out such that the cell separation openings OP2 may divide one channel structure CH into two first channel portion CP1 and second channel portion CP2. In this case, the cell separation openings OP2 may separate the pad pattern layer 157P from an upper end of the channel structure CH such that pad patterns 157a and 157b may be formed.

In this case, the cell separation openings OP2 may have a width equal to a width formed by adding a first thickness t1 of the first insulating layer 131 to a width of the back gate line region BGL of the back gate structure BGS, and may extend in the X-direction. In this case, the stack structure ST in an external region of the channel structure CH may also be cut out, such that the cell separation openings OP2 may expose the gate electrodes 185 and a side surface of the interlayer insulating layer 120.

As illustrated in FIG. 13G, extension openings OP3 extended in the channel structure CH may be formed by removing the entirety of the channel sacrificial layer 116 in the channel structure CH may be removed through the cell separation openings OP2.

Specifically, by selectively removing the channel sacrificial layer 116 exposed in the channel structure CH through each of the cell separation openings OP2, extension openings OP3 having a second width W2 (larger than twice the first thickness t1 of the first insulating layer) may be formed below the pad patterns 157a and 157b in the channel structure CH. The channel layer 150 may be exposed on an internal side surface of the channel structure CH below the pad patterns 157a and 157b.

Accordingly, the cell separation openings OP2 may have a narrow line shape corresponding to the first width W1 on a level of the pad patterns 157a and 157b in an external region of the channel structure CH and above the channel structure CH, and may have an outwardly curved shape having a width corresponding to the maximum second width W2 below the pad patterns 157a and 157b in the channel structure CH.

Referring to FIG. 13H, the first insulating layer 131 may be formed on a side surface and a bottom surface exposed along the cell separation openings OP2.

The first insulating layer 131 may include silicon oxide, and by conformally deposing the silicon oxide on the exposed side surface and bottom surface, a first insulating layer 131 having a first thickness t1 may be disposed on an internal side surface of the channel layer 150, and may be formed on the lower surface and the side surface of the pad patterns 157a and 157b. The first insulating layer 131 may be conformally formed on a side surface of the cell separation openings OP2 dividing the stack structure ST in an external region of the channel structures CH, thereby obtaining electrical insulation between the back gate structure BGS and the gate electrodes 185 formed subsequently.

Referring to FIG. 13I, the back gate structure BGS may be formed on the first insulating layer 131.

The back gate structure BGS may be deposited by filling the conductive material 130 on the first insulating layer 131 through chemical and physical vapor deposition to completely fill a space in the channel hole and the cell separation openings OP2. The conductive material 130 may be over-deposited on the upper interlayer insulating layer 121, may be etched to the upper interlayer insulating layer 121 through chemical etching, and the upper surface of the channel structure CH may be exposed by mechanical polishing. The channel structure CH similarly to an example embodiment of the semiconductor device 100D in FIG. 6 may be formed.

Also, referring to FIG. 13J, an upper opening OP4 may be formed by removing the conductive material 130 of the back gate structure BGS from an upper portion of the channel structure CH to the third length h3.

In this case, the third length h3 may be defined as a depth at which the upper surface of the back gate structure BGS may be disposed on a level lower than a level of a lower surface of the upper gate electrode 185U. By performing etch-back process to lower a level of an upper surface of the back gate structure BGS, fast operation properties may be maintained when the upper gate electrode 185U is driven as an erase transistor or a string select transistor.

Referring to FIG. 13K, the second portion 131T and the protrusion 131P of the first insulating layer 131 may be formed by depositing an insulating material to fill the upper opening OP4.

In this case, when the second portion 131T and the protrusion 131P are formed of the same material as that of the first insulating layer 131, the protrusion 131P of the first insulating layer 131 may be formed as a single layer between the pad patterns 157a and 157b on an upper end of the exposed channel structure CH, and when the insulating material is deposited as a material different from that of the first insulating layer 131, a protrusion 131P including a different insulating material may be formed between the pad patterns 157a and 157b.

The upper insulating layer 190 may be further formed, and contact plugs 147 connected to the channel structures CH may be formed by penetrating the upper insulating layer 190. In this case, the back gate contact 148 may also be formed, and the plugs 148a and 148b for the back gate contact 148 may be formed in two stages.

At least one contact plug 147 may be formed in each of the first and second channel portions CP1 and CP2. The contact plugs 147 may be directly connected to the channel pattern pads 157a and 157b. In some example embodiments, the contact plugs 147 may be formed to be partially recessed into the pad patterns 157a and 157b. The semiconductor device 100 may be manufactured by forming upper interconnection structures 140 including bitlines 140 and a back gate interconnection 145 on the contact plugs 147 and 148.

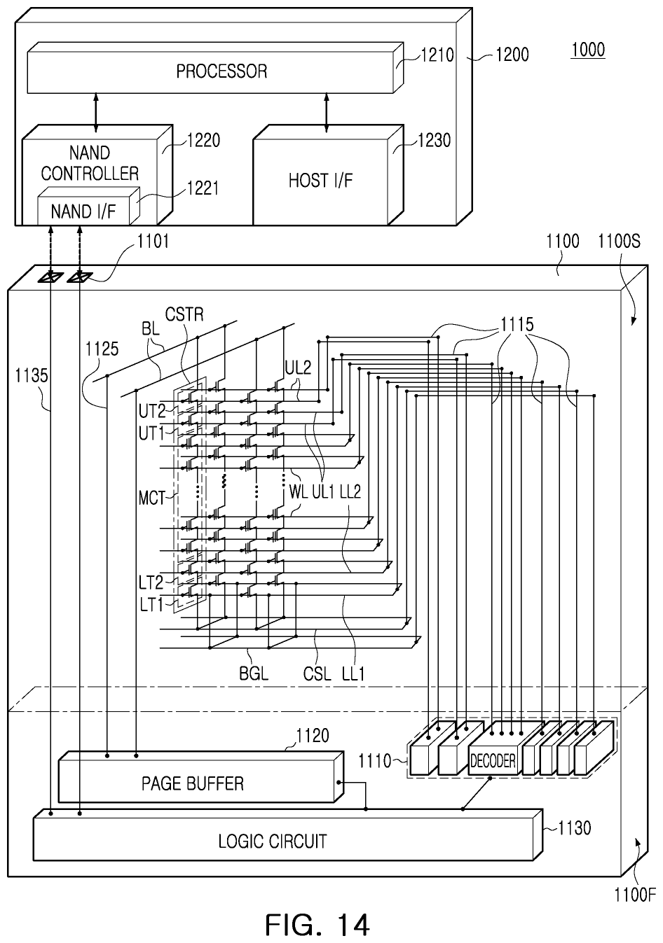

In the description below, a data storage system including a semiconductor device according to an example embodiment will be described with reference to FIGS. 14, 15, and 16.

FIG. 14 is a diagram illustrating a data storage system including a semiconductor device according to an example embodiment.

Referring to FIG. 14, a data storage system 1000 may include a semiconductor device 1100 and a controller 1200 electrically connected to the semiconductor device 1100. The data storage system 1000 may be implemented as a storage device including one or a plurality of semiconductor devices 1100 or an electronic device including a storage device. For example, the data storage system 1000 may be implemented as a solid state drive device (SSD) including one or a plurality of semiconductor devices 1100, a universal serial bus (USB), a computing system, a medical device, or a communication device.

In an example embodiment, the data storage system 1000 may be configured as an electronic system storing data.

The semiconductor device 1100 may be implemented as a non-volatile memory device, such as, for example, the NAND flash memory device described in the aforementioned example embodiment with reference to FIGS. 1 to 12. The semiconductor device 1100 may include a first structure 1100f and a second structure 1100S on the first structure 1100f.

The first structure 1100f may be implemented as a peripheral circuit structure including a decoder circuit 1110, a page buffer 1120, and a logic circuit 1130. For example, the first structure 1100f may include the peripheral circuit structure (PERI in FIG. 2A) described above. The circuit devices described above (21 in FIG. 2A) may be configured as a transistor for the decoder circuit 1110, the page buffer 1120, and the logic circuit 1130.

The second structure 1100S may be implemented as a memory cell structure including a bitline BL, a common source line CSL, a back gate line region BGL, wordlines WL, first and second gate upper lines UL1 and UL2, first and second gate lower lines LL1 and LL2 and memory cell strings CSTR disposed between the bitline BL and the common source line CSL.

The source structure SS described above may include a silicon layer having N-type conductive, and at least a portion of the source structure SS may be included in the common source line CSL.

In the second structure 1100S, each of the memory cell strings CSTR may include lower transistors LT1 and LT2 adjacent to the common source line CSL, upper transistors UT1 and UT2 adjacent to the bitline BL, and a plurality of memory cell transistors MCT disposed between the lower transistors LT1 and LT2 and the upper transistors UT1 and UT2. The number of the lower transistors LT1 and LT2 and the number of the upper transistors UT1 and UT2 may be varied in example embodiments.

The plurality of memory cell transistor MCTs, as described in FIG. 2A, may include intermediate gate electrodes 185M, which may be wordlines, a channel layer 150 of a channel structure CH, a back gate electrode region BGE and a data storage layer 163.

In the example embodiments, the upper transistors UT1 and UT2 may include a string select transistor, and the lower transistors LT1 and LT2 may include a ground select transistor. The gate lower lines LL1 and LL2 may be configured as gate electrodes of the lower transistors LT1 and LT2, respectively. The wordlines WL may be configured as gate electrodes of the memory cell transistors MCT, and the gate upper lines UL1 and UL2 may be configured as gate electrodes of the upper transistors UT1 and UT2, respectively.

The gate electrodes (FIG. 2A, 185) described above may be included in the gate lower lines LL1 and LL2, the wordlines WL and the gate upper lines UL1 and UL2.

The common source line CSL, the back gate line BGL, the first and second gate lower lines LL1 and LL2, the wordlines WL, and the first and second gate upper lines UL1 and UL2 in the first structure 1100f may be electrically connected to the decoder circuit 1110 through the first connection interconnections 1115 extending to the second structure 1100S.

The bitlines 140 BL may be electrically connected to the page buffer 1120 through second connection interconnections 1125 extending from the first structure 1100f to the second structure 1100S. The bitlines BL may be the bitlines 140 described above.

In the first structure 1100f, the decoder circuit 1110 and the page buffer 1120 may perform a control operation on at least one selected memory cell transistor among the plurality of memory cell transistors MCT. The decoder circuit 1110 and the page buffer 1120 may be controlled by the logic circuit 1130.

The semiconductor device 1000 may further include an input/output pad 1101. The semiconductor device 1100 may communicate with the controller 1200 through the input/output pad 1101 electrically connected to the logic circuit 1130. The input/output pads 1101 may be electrically connected to the logic circuit 1130 through an input/output connection line 1135 extending from the first structure 1100f to the second structure 1100S. Accordingly, the controller 1200 may be electrically connected to the semiconductor device 1000 through the input/output pad 1101 and may control the semiconductor device 1000.

The controller 1200 may include a processor 1210, a NAND controller 1220, and a host interface 1230. In the example embodiments, the data storage system 1000 may include a plurality of semiconductor devices 1100, and in this case, the controller 1200 may control the plurality of semiconductor devices 1100.

The processor 1210 may control overall operation of the data storage system 1000 including the controller 1200. The processor 1210 may operate according to a predetermined firmware, and may access the semiconductor device 1100 by controlling the NAND controller 1220. The NAND controller 1220 may include a controller interface 1221 processing communication with the semiconductor device 1100. Through the controller interface 1221, a control command for controlling the semiconductor device 1100, data to be written to the memory cell transistors MCT of the semiconductor device 1100, and data to be read from the memory cell transistors MCT of the semiconductor device 1100 may be transmitted. The host interface 1230 may provide a communication function between the data storage system 1000 and an external host. When a control command from an external host is received through the host interface 1230, the processor 1210 may control the semiconductor device 1100 in response to the control command.

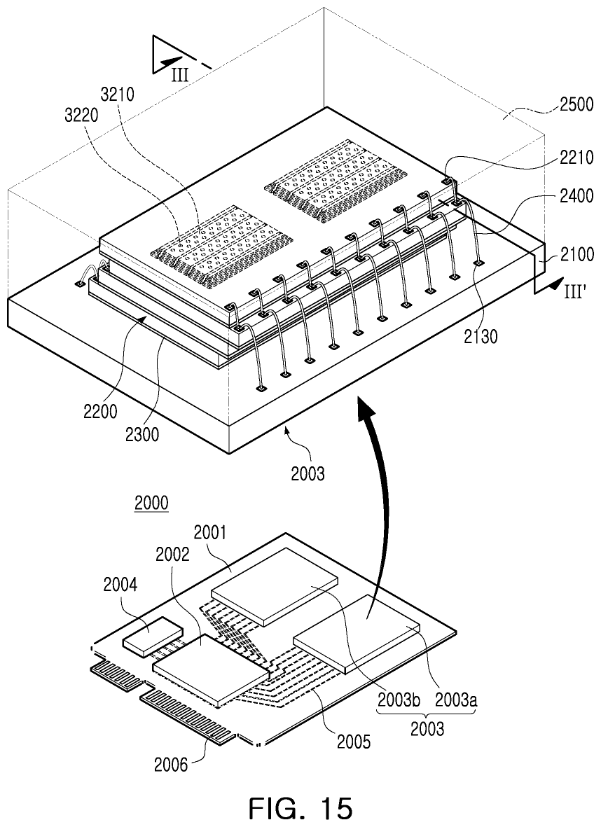

FIG. 15 is a perspective diagram illustrating a data storage system including a semiconductor device according to an example embodiment.

Referring to FIG. 15 a data storage system 2000 in an example embodiment may include a main board 2001, a controller 2002 mounted on the main board 2001, one or more semiconductor packages 2003, and a DRAM 2004. The semiconductor package 2003 and the DRAM 2004 may be connected to the controller 2002 by interconnection patterns 2005 formed on the main board 2001.

The main board 2001 may include a connector 2006 including a plurality of pins coupled to an external host. The number and arrangement of the plurality of pins in the connector 2006 may be varied depending on a communication interface between the data storage system 2000 and the external host. In the example embodiments, the data storage system 2000 may communicate with an external host according to one of interfaces from among universal serial bus (USB), peripheral component interconnect express (PCI-Express), serial advanced technology attachment (SATA), M-Phy for universal flash storage (UFS). In the example embodiments, the data storage system 2000 may operate by power supplied from an external host through the connector 2006. The data storage system 2000 may further include a power management integrated circuit (PMIC) for distributing power supplied from the external host to the controller 2002 and the semiconductor package 2003.

The controller 2002 may write data to or may read data from the semiconductor package 2003, and may improve an operating speed of the data storage system 2000.

The DRAM 2004 may be configured as a buffer memory for alleviating a difference in speeds between the semiconductor package 2003, which is a data storage space, and an external host. The DRAM 2004 included in the data storage system 2000 may operate as a cache memory, and may provide a space for temporarily storing data in a control operation for the semiconductor package 2003. When the data storage system 2000 may include the DRAM 2004, the controller 2002 may further include a DRAM controller for controlling the DRAM 2004 in addition to the NAND controller for controlling the semiconductor package 2003.

The semiconductor package 2003 may include first and second semiconductor packages 2003a and 2003b spaced apart from each other. Each of the first and second semiconductor packages 2003a and 2003b may be configured as a semiconductor package including a plurality of semiconductor chips 2200. Each of the semiconductor chips 2200 may include a semiconductor device according to one of the example embodiments described above with reference to FIGS. 1 to 12.

Each of the first and second semiconductor packages 2003a and 2003b may include a package substrate 2100, semiconductor chips 2200 on the package substrate 2100, adhesive layers 2300 disposed on lower surfaces of the semiconductor chips 2200, a connection structure 2400 electrically connecting the semiconductor chips 2200 and the package substrate 2100, and a molding layer 2500 covering the semiconductor chips 2200 and the connection structure 2400 on the package substrate 2100.

The package substrate 2100 may be configured as a printed circuit board including package upper pads 2130. Each of the semiconductor chips 2200 may include an input/output pad 2210.

In the example embodiments, the connection structure 2400 may be configured as a bonding wire electrically connecting the input/output pad 2210 to the upper package pads 2130. Accordingly, in each of the first and second semiconductor packages 2003a and 2003b, the semiconductor chips 2200 may be electrically connected to each other by a bonding wire method, and may be electrically connected to the package upper pads 2130 of the package substrate 2100. In the example embodiments, in each of the first and second semiconductor packages 2003a and 2003b, the semiconductor chips 2200 may be electrically connected to each other by a connection structure including a through-electrode (TSV) instead of the connection structure 2400 of a bonding wire method.

In the example embodiments, the controller 2002 and the semiconductor chips 2200 may be included in a single package. In an example embodiment, the controller 2002 and the semiconductor chips 2200 may be mounted on an interposer substrate different from the main board 2001, and the controller 2002 and the semiconductor chips 2200 may be connected to each other by interconnection formed on the interposer substrate.

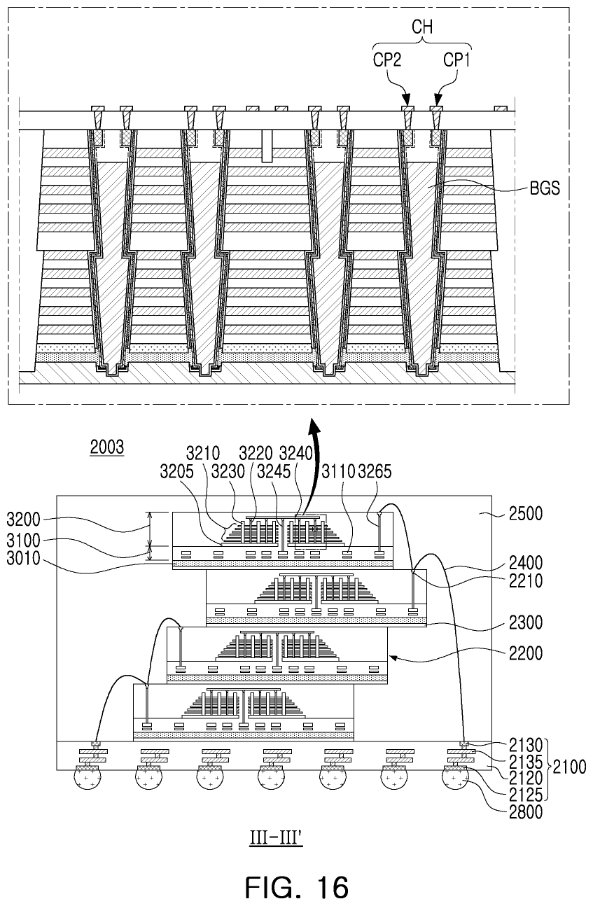

FIG. 16 is a cross-sectional diagram illustrating a semiconductor package according to an example embodiment. FIG. 16 illustrates an example embodiment of the semiconductor package 2003 in FIG. 15 taken along line III-III′.

Referring to FIG. 16, in a semiconductor package 2003, the package substrate 2100 may be implemented as a printed circuit substrate. The package substrate 2100 may include may include a package substrate body portion 2120, package upper pads 2130 disposed on an upper surface of the package substrate body portion 2120, lower pads 2125 disposed on the lower surface of the package substrate body 2120 or exposed through the lower surface, and internal interconnections 2135 electrically connecting the upper pads 2130 to the lower pads 2125 in the package substrate body 2120. The lower pads 2125 may be connected to the interconnection patterns 2005 of the main the substrate 2001 of the data storage system 2000 through the conductive connection portions 2800.

Each of the semiconductor chips 2200 may include a first structure 3100 and a second structure 3200 stacked in order on the semiconductor substrate 3010 and semiconductor substrate 3010. The first structure 3100 may include a peripheral circuit region including peripheral interconnections 3110. The second structure 3200 may include a common source line 3205, a stack structure 3210 on the common source line 3205, memory channel structures 3220 and separation structures 3230 penetrating the stack structure 3210, bitlines 3240 electrically connected to memory channel structures 3220, and gate contact plugs electrically connected to the wordlines WL of the stack structure 3210. The first structure 3100 may include the first structure 1100f in FIG. 14, and the second structure 3200 may include the second structure 1100S in FIG. 14.

Each of the semiconductor chips 2200 may include a through-interconnection 3245 electrically connected to the peripheral interconnections 3110 of the first structure 3100 and extending into the second structure 3200. The through-interconnection 3245 may penetrate the stack structure 3210 and may be further disposed on an external side of the stack structure 3210.

Each of the semiconductor chips 2200 may further include an input/output connection interconnection 3265 electrically connected to the peripheral interconnections 3110 of the first structure 3100 and extending into the second structure 3200, and an input/output pad 2210 electrically connected to the input/output interconnection 3265.

In FIG. 16, the enlarged portion may indicate that the semiconductor chips 2200 in FIG. 16 may be modified to include the same cross-sectional structure as in FIG. 2A. Accordingly, each of the semiconductor chips 2200 may include a semiconductor device 100 according to one of the example embodiments described above with reference to FIGS. 5 to 12, instead of the semiconductor device according to the example embodiment in FIG. 2A.

According to the aforementioned example embodiments, by including a data storage layer applying a ferroelectric layer for storing a data using polarization state and applying the back gate voltage through the back gate electrode region, when a program voltage or detection voltage is applied to a selected cell, the electric field effect on neighboring unselected cells may be reduced.

Also, by forming the back gate electrode region by cutting the channel structure to connect to a neighboring channel structure, the channel structure may be divided into two channel portions such that memory capacity may be ensured, and parasitic capacitance between the wordline and the channel structure may be reduced. Also, a back gate electrode region may be shared between the two channel portions, such that the number of contacts may be significantly reduced.

Also, the back gate electrode region of the plurality of channel structures forming a row may be formed as a line structure, such that a contact of the back gate electrode region may not be formed in the channel structure, and the contact of the back gate electrode region may not be disposed on a boundary region such that a pitch of the bitline contact on the channel structure may not be affected. Also, the contacts of the back gate electrode regions in the plurality of channel structures in a memory block may be connected to each other, such that the back gate voltage may be applied simultaneously.

While the example embodiments have been illustrated and described above, it will be configured as apparent to those skilled in the art that modifications and variations could be made without departing from the scope of the present disclosure as defined by the appended claims.

What is claimed is:

1. A semiconductor device, comprising:
a source structure;
a stack structure including interlayer insulating layers and gate electrodes stacked in a first direction perpendicular to an upper surface of the source structure;
channel structures disposed in channel holes penetrating the stack structure in the first direction, the channel structures including a gate dielectric structure and a channel layer; and
a back gate structure dividing each of the channel structures into a first channel portion and a second channel portion, and extending in a second direction perpendicular to the first direction,
wherein the back gate structure includes:
back gate electrode regions disposed between the first channel portion and the second channel portion of each of the channel structures, and filling the channel hole; and
back gate line regions penetrating the stack structure and connecting the back gate electrode regions to each other in the second direction.

2. The semiconductor device of claim 1, wherein a maximum width of each of the back gate electrode regions is greater than a maximum width of each of the back gate line regions.

3. The semiconductor device of claim 1, wherein an upper surface of the back gate structure is disposed on a level lower than a level of an upper surface of the channel structure.

4. The semiconductor device of claim 1, wherein an upper surface of the back gate structure is disposed on a level lower than a level of a lower surface of the upper gate electrode of the stack structure.

5. The semiconductor device of claim 1, wherein each of the channel structures further includes:
a first pad pattern disposed in an upper portion of the channel structure and connected to the channel layer of the first channel portion; and
a second pad pattern disposed in an upper portion of the channel structure, spaced apart from the first pad pattern, and connected to the channel layer of the second channel portion.

6. The semiconductor device of claim 5, further comprising:
a first insulating layer surrounding the back gate structure.

7. The semiconductor device of claim 6, wherein the first insulating layer includes:
a side first insulating layer disposed on a side surface and a bottom surface of the back gate structure; and
an upper first insulating layer disposed on an upper surface of the back gate structure and including a protrusion protruding into a space between the first pad pattern and the second pad pattern.

8. The semiconductor device of claim 6,
wherein the back gate electrode region includes a protrusion region protruding into a space between the first pad pattern and the second pad pattern, and
wherein the first insulating layer is disposed between the protrusion region and the first pad pattern and the second pad pattern.

9. The semiconductor device of claim 6, wherein a lower surface of the channel layer on a lower end of the channel structure is disposed on a level higher than a level of a lower surface of the first insulating layer on a lower end of the back gate structure.

10. The semiconductor device of claim 6, wherein the gate dielectric structure includes:
a data storage layer between the channel layer and the gate electrodes; and
a second insulating layer between the data storage layer and the gate electrodes.

11. The semiconductor device of claim 1, wherein a lower end of the channel structure is disposed on a level higher than a level of a lower end of the back gate structure.

12. The semiconductor device of claim 1, wherein the channel structure has a first length in the second direction, and a second length greater than the first length in a third direction perpendicular to the first and second directions, and the back gate electrode region is disposed in a central region of the channel structure.

13. The semiconductor device of claim 1,
wherein the channel structure has a first length in a first diagonal direction inclined to the second direction, and a second length greater than the first length in a second diagonal direction perpendicular to the first diagonal direction, and
wherein the back gate electrode region is disposed in a center of the channel structure in the second and third directions, and the back gate line region extends in the second direction.

14. A semiconductor device, comprising:
a plate layer;
a stack structure including interlayer insulating layers and gate electrodes stacked on the plate layer in a first direction perpendicular to the plate layer, and including a channel hole extending in the first direction;
a common back gate electrode filling a central region of the channel hole, extending in a second direction perpendicular to the first direction, dividing the channel hole into a first space and a second space, and having a first side surface exposed to the first space and a second side surface exposed to the second space;
a first channel portion disposed in the first space of the channel hole and including a first gate dielectric structure, a first channel layer, and a first pad pattern connected to the first channel layer;
a second channel portion disposed in the second space of the channel hole and including a second gate dielectric structure, a second channel layer isolated from the first channel layer, and a second pad pattern connected to the second channel layer and isolated from the first pad pattern; and
bitlines extending in a third direction perpendicular to the first and second directions and electrically connected to the first and second pad patterns, respectively,
wherein the first side surface of the common back gate electrode includes a curved surface protruding toward the first channel layer, and the second side surface includes a curved surface protruding toward the second channel layer.

15. The semiconductor device of claim 14, further comprising:
a back gate contact electrically connected to the common back gate electrode in an external region of the channel hole.

16. The semiconductor device of claim 15, further comprising:
a back gate line region penetrating the stack structure and connecting the common back gate electrode to the common back gate electrode of a neighboring channel hole,
wherein the back gate line region is electrically connected to the back gate contact.

17. The semiconductor device of claim 14, further comprising:
an insulating layer between the common back gate electrode and the first and second channel layers.

18. The semiconductor device of claim 14, wherein each of the first and second gate dielectric structures includes a ferroelectric layer between the first and second channel layers and the gate electrodes.

19. A data storage system, comprising:
a semiconductor device including an input/output pad; and
a controller electrically connected to the semiconductor device through the input/output pad and controlling the semiconductor device,
wherein the semiconductor device includes:
a source structure;
a stack structure including interlayer insulating layers and gate electrodes stacked in a first direction perpendicular to an upper surface of the source structure;
channel structures disposed in channel holes penetrating the stack structure in the first direction, the channel structures including a gate dielectric structure and a channel layer; and
a back gate structure dividing each of the channel structures into a first channel portion and a second channel portion and extending in a second direction perpendicular to the first direction,
wherein the back gate structure includes:
back gate electrode regions disposed between the first channel portion and the second channel portion of each of the channel structures, and filling the channel hole; and
back gate line regions penetrating the stack structure and connecting the back gate electrode regions to each other in the second direction.

20. The data storage system of claim 19, wherein a maximum width of the back gate electrode regions is greater than a maximum width of the back gate line regions.
